(19) United States
(12) Patent Application Publication
(10) Pub. No.: US 2026/0074004 A1
(43) Pub. Date: Mar. 12, 2026

(54) MEMORY DEVICE, TESTING METHOD OF MEMORY DEVICE, AND MANUFACTURING METHOD OF MEMORY DEVICE

(71) Applicant: Kioxia Corporation, Tokyo (JP)

(72) Inventors: Kenji SAKAUE, Yokohama (JP); Yasuhiko KUROSAWA, Fujisawa (JP)

(73) Assignee: Kioxia Corporation, Tokyo (JP)

(21) Appl. No.: 19/061,358

(22) Filed: Feb. 24, 2025

(30) Foreign Application Priority Data
Sep. 12, 2024 (JP) 2024-158122

(51) Int. Cl. G11C 29/10; H01L 25/065; H01L 25/18; H10B 80/00

(52) U.S. Cl. CPC G11C 29/10; H10B 80/00; H10W 90/00; H10W 90/297

(57) ABSTRACT

According to one embodiment, a memory device includes a first chip, a second chip stacked above the first chip, and a switching circuit. The second chip includes a substrate, a memory cell array, and first to third vias each passing through the substrate and connected to the first chip. The switching circuit is configured to switch among: a first state in which, between the first and second chips, first and second signals are communicated through the first and second vias respectively; a second state in which, between the first and second chips, the first and second signals are communicated through the third and second vias respectively; and a third state in which, between the first and second chips, the first and second signals are communicated through the first and third vias respectively.

### CROSS-REFERENCE TO RELATED APPLICATION

This application is based upon and claims the benefit of priority from Japanese Patent Application No. 2024-158122, filed Sep. 12, 2024, the entire contents of which are incorporated herein by reference.

### FIELD

Embodiments described herein relate generally to a memory device, a testing method of a memory device, and a manufacturing method of a memory device.

### BACKGROUND

A memory system including a NAND flash memory as a memory device and a memory controller that controls the memory device is known. The memory device includes a plurality of core chips and an interface chip. Each of the core chips stores data in a non-volatile manner. The interface chip controls communication between the memory controller and the core chips.

### BRIEF DESCRIPTION OF DRAWINGS

FIG. 1 is a block diagram showing an example of a configuration of an information processing system according to a first embodiment.

FIG. 2 is a block diagram showing an example of a functional configuration of a memory device and its connection with a memory controller according to the first embodiment.

FIG. 3 is a circuit diagram showing a first implementation example of a TSV switching circuit included in the memory device according to the first embodiment.

FIG. 4 is a circuit diagram showing a second implementation example of a TSV switching circuit included in the memory device according to the first embodiment.

FIG. 5 is a diagram showing an example of a relationship among signals transmitted by the TSV switching circuit according to the first embodiment.

FIG. 6 is a circuit diagram showing a first implementation example of a TSV switching circuit included in a memory device according to a first modification of the first embodiment.

FIG. 7 is a circuit diagram showing a second implementation example of a TSV switching circuit included in the memory device according to the first modification of the first embodiment.

FIG. 8 is a circuit diagram showing a first implementation example of a TSV switching circuit included in a memory device according to a second modification of the first embodiment.

FIG. 9 is a circuit diagram showing a second implementation example of a TSV switching circuit included in the memory device according to the second modification of the first embodiment.

FIG. 10 is a circuit diagram showing an implementation example of a TSV switching circuit included in a memory device according to a third modification of the first embodiment.

FIG. 11 is a circuit diagram showing an implementation example of a TSV switching circuit included in a memory device according to a fourth modification of the first embodiment.

FIG. 12 is a block diagram showing an example of a functional configuration related to a test process in a memory device according to a second embodiment.

FIG. 13 is a flowchart showing an example of the test process in the memory device according to the second embodiment.

FIG. 14 is a block diagram showing an example of a functional configuration related to a test process in a memory device according to a modification of the second embodiment.

FIG. 15 is a block diagram showing an example of a functional configuration related to a test process of a memory device according to a third embodiment.

FIG. 16 is a flowchart showing an example of the test process in the memory device according to the third embodiment.

FIG. 17 is a block diagram showing an example of a functional configuration related to a test process in a memory device according to a fourth embodiment.

FIG. 18 is a flowchart showing an example of a test process related to redundant vias in the memory device according to the fourth embodiment.

FIG. 19 is a flowchart showing an example of a test process related to default vias in the memory device according to the fourth embodiment.

FIG. 20 is a block diagram showing an example of a functional configuration related to a test process of a memory device according to a modification of the fourth embodiment.

FIG. 21 is a block diagram showing an example of a functional configuration related to a test process of a memory device according to a fifth embodiment.

FIG. 22 is a flowchart showing an example of the test process in the memory device according to the fifth embodiment.

### DETAILED DESCRIPTION

In general, according to one embodiment, a memory device includes a first chip; a second chip stacked above the first chip, the second chip including a substrate, a memory cell array configured to store data in a non-volatile manner, a first via, a second via, and a third via, each of the first to third vias passing through the substrate in a stacking direction and being connected to the first chip; and a switching circuit configured to switch among: a first state in which, between the first chip and the second chip, a first signal is communicated through the first via and a second signal is communicated through the second via; a second state in which, between the first chip and the second chip, the first signal is communicated through the third via and the second signal is communicated through the second via; and a third state in which, between the first chip and the second chip, the first signal is communicated through the first via and the second signal is communicated through the third via.

Hereinafter, embodiments will be described with reference to the drawings. In the following description, components having the same function and configuration are denoted by the same reference numerals. In addition, in a case where a plurality of components having the common reference sign is distinguished, a suffix for distinguishing the components is added to the common reference sign. Note that, in a case where a plurality of constituent elements does not need to be particularly distinguished, only common reference numerals are attached to the constituent elements, and no suffixes are attached thereto.

### 1. First Embodiment

### 1.1 Configuration

### 1.1.1 Information Processing System

A configuration of an information processing system according to a first embodiment will be described.

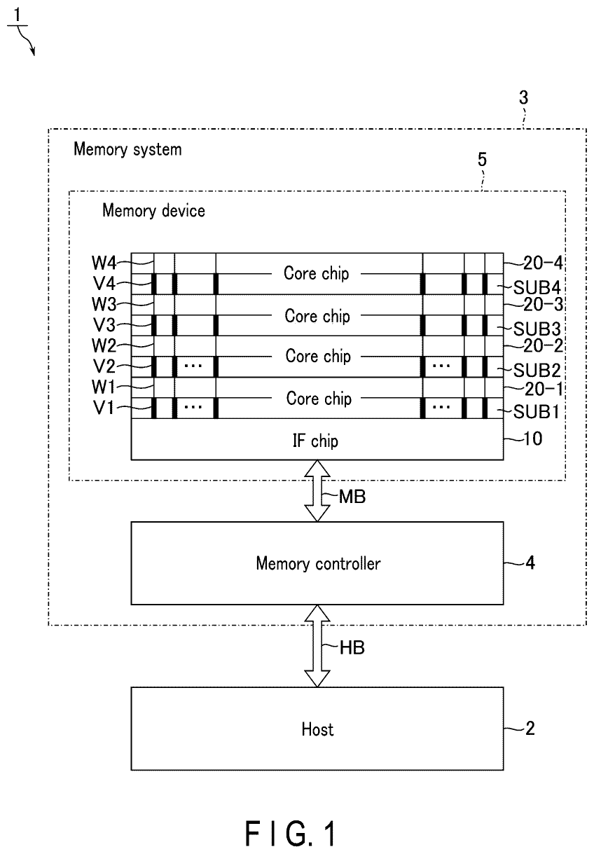

FIG. 1 is a block diagram showing an example of a configuration of the information processing system according to the first embodiment. As shown in FIG. 1, an information processing system 1 includes a host 2 and a memory system 3. The host 2 and the memory system 3 are connected through a host bus HB. The host bus HB conforms to, for example, an SD™ interface, M-PHY™, SAS (Serial Attached SCSI (Small Computer System Interface)), SATA (Serial ATA (Advanced Technology Attachment), or Peripheral Component Interconnect Express (PCIe™).

The host 2 is, for example, a server in a data center, a personal computer, or a mobile terminal. The host 2 performs information processing using data stored in the memory system 3.

The memory system 3 is a memory device configured to be connected to the host 2. The memory system 3 is, for example, a memory card such as an SD™ card, a universal flash storage (UFS), or a solid state drive (SSD). The memory system 3 executes a write process, a read process, and an erase process of data in response to a request from the host 2.

### 1.1.2 Memory System

Next, an internal configuration of the memory system 3 will be described with reference to FIG. 1. As shown in FIG. 1, the memory system 3 includes a memory controller 4 and a memory device 5.

The memory controller 4 is implemented with, for example, an integrated circuit such as a system-on-a-chip (SoC). The memory controller 4 may include a plurality of semiconductor chips. The memory controller 4 controls the memory device 5 based on a request from the host 2.

Specifically, for example, the memory controller 4 executes a write process of writing data to the memory device 5 based on a write command from the host 2. The memory controller 4 executes a read process of reading data written in the write process from the memory device 5 based on a read command from the host 2.

The memory device 5 is, for example, a semiconductor package that functions as a NAND flash memory. The memory device 5 includes an interface chip (IF chip) 10 and a plurality of core chips 20-1, 20-2, 20-3, and 20-4. Note that although the example of FIG. 1 shows a case where four core chips 20-1 to 20-4 are mounted, any number of core chips, including only one core chip, can be mounted in the memory device 5.

The IF chip 10 is a semiconductor chip that controls communication between the memory controller 4 and the core chips 20-1 to 20-4. The IF chip 10 is connected to the memory controller 4 through a memory bus MB. The memory bus MB conforms to, for example, a single data rate (SDR) interface, a toggle double data rate (DDR) interface, or an open NAND flash interface (ONFI).

The core chips 20-1, 20-2, 20-3, and 20-4 are semiconductor chips that store data in a non-volatile manner. The core chips 20-1, 20-2, 20-3, and 20-4 are stacked above the IF chip 10 in this order, for example.

The core chip 20-1 includes a plurality of vias V1 and a plurality of interconnects W1. Each of the vias V1 is a through silicon via (TSV) penetrating a semiconductor substrate SUB1 of the core chip 20-1. Each of the vias V1 electrically connects the IF chip 10 and the corresponding interconnect W1. In other words, the core chip 20-1 communicates with the IF chip 10 through the vias V1.

The core chip 20-2 includes a plurality of vias V2 and a plurality of interconnects W2. Each of the vias V2 is a TSV penetrating a semiconductor substrate SUB2 of the core chip 20-2. Each of the vias V2 electrically connects the corresponding interconnect W1 of the core chip 20-1 and the corresponding interconnect W2 of the core chip 20-2. In other words, the core chip 20-2 communicates with the IF chip 10 through the vias V2 and V1.

The core chip 20-3 includes a plurality of vias V3 and a plurality of interconnects W3. Each of the vias V3 is a TSV penetrating a semiconductor substrate SUB3 of the core chip 20-3. Each of the vias V3 electrically connects the corresponding interconnect W2 of the core chip 20-2 and the corresponding interconnect W3 of the core chip 20-3. In other words, the core chip 20-3 communicates with the IF chip 10 through the vias V3, V2, and V1.

The core chip 20-4 includes a plurality of vias V4 and a plurality of interconnects W4. Each of the vias V4 is a TSV penetrating a semiconductor substrate SUB4 of the core chip 20-4. Each of the vias V4 electrically connects the corresponding interconnect W3 of the core chip 20-3 and the corresponding interconnect W4 of the core chip 20-4. In other words, the core chip 20-4 communicates with the IF chip 10 through the vias V4, V3, V2, and V1.

Hereinafter, the vias V1 to V4 and the interconnects W1 to W4 connected to each other may be regarded as an integrated via. In this case, the vias V1 to V4 and the interconnects W1 to W4 regarded as integrated vias are simply referred to as a vias V.

### 1.1.3 Memory Device

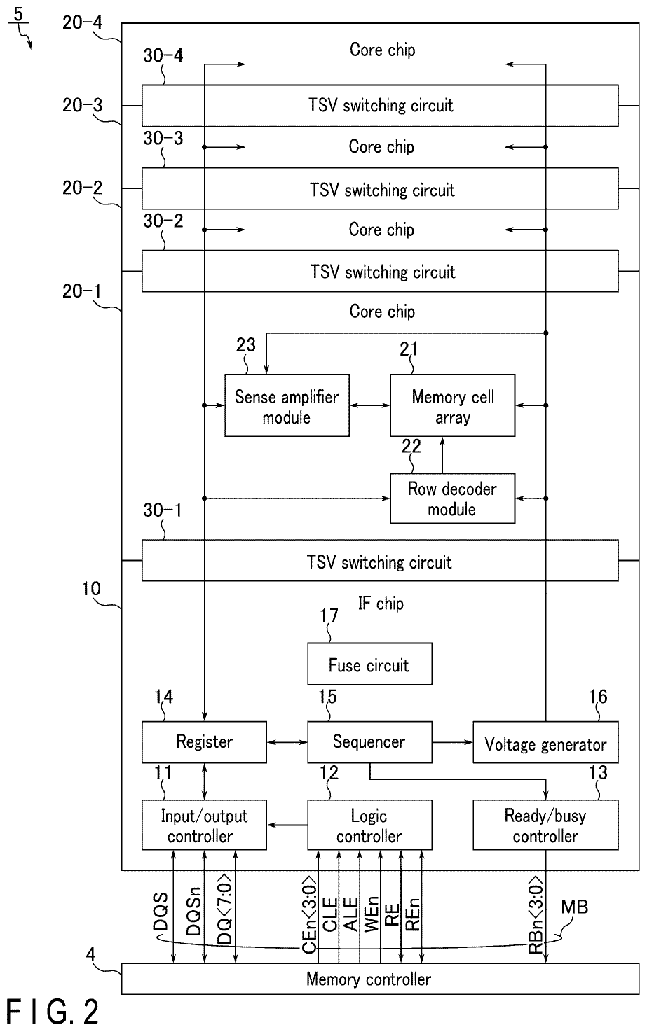

FIG. 2 is a block diagram showing an example of a functional configuration of the memory device and its connection with the memory controller according to the first embodiment. As shown in FIG. 2, the IF chip 10 includes an input/output controller 11, a logic controller 12, a ready/busy controller 13, a register 14, a sequencer 15, a voltage generator 16, and a fuse circuit 17. The core chip 20-1 includes a memory cell array 21, a row decoder module 22, and a sense amplifier module 23. Although not shown in FIG. 2, each of the core chips 20-2, 20-3, and 20-4 includes a configuration equivalent to that of the core chip 20-1.

In addition, a TSV switching circuit 30-1 is provided logically across both the IF chip 10 and the core chip 20-1. A TSV switching circuit 30-2 is provided logically across both the core chip 20-1 and the core chip 20-2. A TSV switching circuit 30-3 is provided logically across both the core chip 20-2 and the core chip 20-3. A TSV switching circuit 30-4 is provided logically across both the core chip 20-3 and the core chip 20-4. Note that the TSV switching circuit 30-1 can be physically disposed in any place of the IF chip 10 and in any place of each of the core chips 20-1, 20-2, 20-3, and 20-4.

The input/output controller 11, the logic controller 12, and the ready/busy controller 13 transmit and receive various signals to and from the memory controller 4 through the memory bus MB. The signals transmitted and received by the input/output controller 11 include, for example, signals DQ<7:0>, DQS, and DQSn. The signals received by the logic controller 12 include, for example, signals CEn<3:0>, CLE, ALE, WEn, RE, and REn. The ready/busy controller 13 transmits signals RBn<3:0>. In this specification, “n” at the end of the name of a signal represents that the signal is asserted in a case where the signal is at a low level. Hereinafter, a signal transmitted from the memory controller 4 to the memory device 5 is referred to as an input signal. A signal transmitted from the memory device 5 to the memory controller 4 is called an output signal.

The signals DQ<7:0> are an 8-bit signal. The signals DQ<7:0> are a bidirectional signal and is an entity of data transmitted and received between the memory device 5 and the memory controller 4. Hereinafter, the signals DQ<7:0> are referred to as input data DQ<7:0> in a case where transmitted from the memory controller 4 to the memory device 5. Further, the signals DQ<7:0> are referred to as output data DQ<7:0> in a case where transmitted from the memory device 5 to the memory controller 4. The input data DQ<7:0> includes, for example, write data, address information, and a command. The output data DQ<7:0> includes, for example, read data.

The signals DQS and DQSn are bidirectional signals, and are strobe signals for the signals DQ<7:0>. The signal DQSn is an inverted signal of the signal DQS. The signals DQS and DQSn are output signals in a case where the signals DQ<7:0> are an output signal, and are input signals in a case where the signals DQ<7:0> are an input signal.

The signals CEn<3:0> are an input signal for enabling the core chips 20-1, 20-2, 20-3, and 20-4. For example, the signals CEn<0>, CEn<1>, CEn<2>, and CEn<3> of the signals CEn<3:0> correspond to the core chips 20-1, 20-2, 20-3, and 20-4, respectively.

The signals CLE and ALE are input signals for notifying the memory device 5 that the input signals DQ<7:0> are a command and address information, respectively.

The signal WEn is an input signal for causing the memory device 5 to latch the input data DQ<7:0>.

The signals RE and REn are input signals for reading the output data DQ<7:0> from the memory device 5. The signal REn is an inverted signal of the signal RE.

The signals RBn<3:0> are an output signal indicating whether the core chips 20-1, 20-2, 20-3, and 20-4 are in a ready state or a busy state. For example, the signals RBn<0>, RBn<1>, RBn<2>, and RBn<3> of the signals RBn<3:0> correspond to the core chips 20-1, 20-2, 20-3, and 20-4, respectively. The ready state is a state in which the core chip 20 can receive a command from the memory controller 4. The busy state is a state in which the core chip 20 cannot receive a command from the memory controller 4. The low-level signals RBn<3:0> indicate a busy state.

The input/output controller 11 receives input data DQ<7:0> from the memory controller 4. The input/output controller 11 extracts address information, a command, and write data from the input data DQ<7:0>, and transmits them to the register 14. The input/output controller 11 reads read data from the register 14 and outputs the read data to the memory controller 4 as output data DQ<7:0>. The logic controller 12 receives signals CEn<3:0>, CLE, ALE, WEn, RE, and REn from the memory controller 4. The ready/busy controller 13 transmits the signals RBn<3:0> received from the sequencer 15 to the memory controller 4.

The register 14 temporarily stores address information, a command, write data, and read data, for each of the core chips 20-1, 20-2, 20-3, and 20-4. The address information includes, for example, a column address, a block address, and a page address. The sequencer 15 controls the entire operation of the memory device 5 based on the command stored in the register 14. The voltage generator 16 generates various voltages used in a write process, a read process, an erase process, and the like. The address information and the write data stored in the register 14, a control signal generated by the sequencer 15, and various voltages generated by the voltage generator 16 are supplied to the memory cell array 21, the row decoder module 22, and the sense amplifier module 23 of each of the core chips 20-1, 20-2, 20-3, and 20-4 through the TSV switching circuits 30-1, 30-2, 30-3, and 30-4. Read data read by the sense amplifier module 23 from the memory cell array 21 of each of the core chips 20-1, 20-2, 20-3, and 20-4 is stored in the register 14 through the TSV switching circuits 30-1, 30-2, 30-3, and 30-4.

The fuse circuit 17 is a circuit that stores settings of the TSV switching circuits 30-1, 30-2, 30-3, and 30-4 to be described later. For storing the settings, the fuse circuit 17 may be, for example, a fuse that fuses a metal component or the like, or may be an electronic fuse.

The memory cell array 21 includes a plurality of blocks, a plurality of bit lines, and a plurality of word lines. The block is, for example, a unit of erasing data in the erase process. Each of the blocks includes a plurality of memory cells. The memory cell is, for example, a unit of an element that stores data in a non-volatile manner. Each of the memory cells is associated with a set of a bit line and a word line.

The row decoder module 22 selects one block in the corresponding memory cell array 21 based on a block address in the register 14. The row decoder module 22 further selects a word line in the selected block based on a page address in the register 14.

The sense amplifier module 23 selects a bit line based on the column address in the register 14. In the write process, the sense amplifier module 23 transfers write data to the memory cell array 21 through the selected bit line. In the read process, the sense amplifier module 23 senses the threshold voltage of a memory cell through the selected bit line. Then, the sense amplifier module 23 generates read data based on the sensing result and transmits the generated read data to the register 14.

The TSV switching circuit 30-1 has a function of switching the TSV used for communication of a predetermined signal between the IF chip 10 and the core chip 20-1 among the vias V1. The TSV switching circuit 30-2 has a function of switching TSV used for communication of a predetermined signal between the core chip 20-1 and the core chip 20-2 among the vias V2. The TSV switching circuit 30-3 has a function of switching TSV used for communication of a predetermined signal between the core chip 20-2 and the core chip 20-3 among the vias V3. The TSV switching circuit 30-4 has a function of switching TSV used for communication of a predetermined signal between the core chip 20-3 and the core chip 20-4 among the vias V4.

In the following description, it is assumed that a predetermined TSV is allocated in advance to communication of a predetermined signal. The predetermined TSV assigned in advance to the predetermined signal is also referred to as a “default via”. A TSV to be used by switching from the default via for communication of a predetermined signal is also referred to as a “redundant via”. A TSV used for other communication (for example, a control signal used for via switching) is also referred to as a “control via”. The control via may be either a default via or a redundant via.

Note that, in switching from the default via to the redundant via in communication of a signal between the IF chip 10 and the core chip 20-4, a TSV to be actually switched may be at least one of the vias V1, V2, V3, and V4. In a first implementation example and a second implementation example of the first embodiment described below, for convenience of description, in a case where switching from the default via to the redundant via is performed, it is assumed that all of the vias V1, V2, V3, and V4 are switched.

### 1.1.4 TSV Switching Circuit

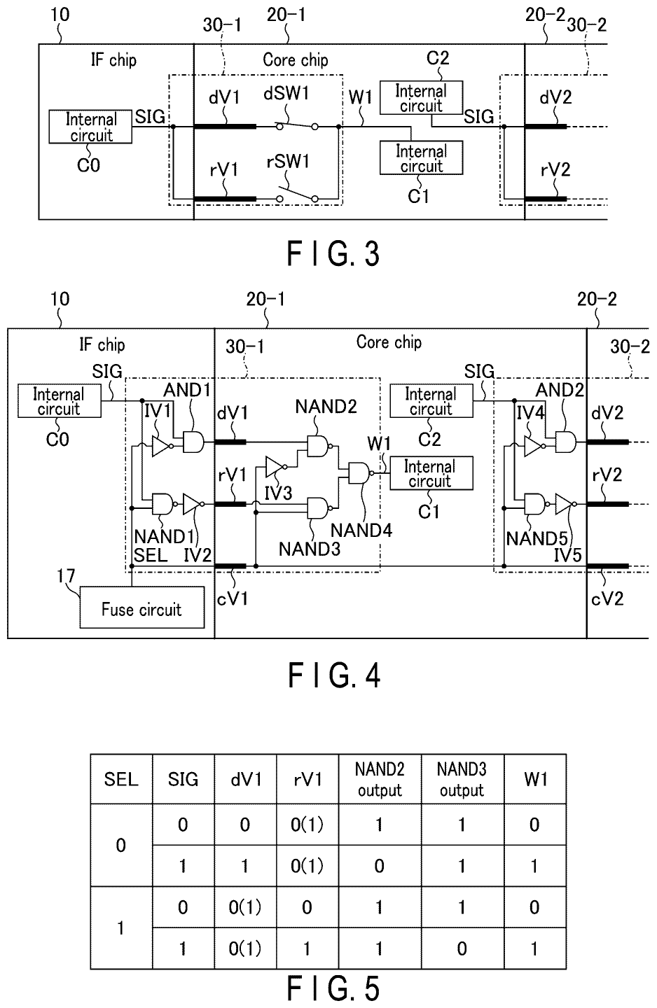

An implementation example of the TSV switching circuit included in the memory device according to the first embodiment will be described with reference to FIGS. 3 to 11. FIGS. 3 to 11 mainly show implementation examples of the TSV switching circuit 30-1 related to a unidirectional signal transmitted from the IF chip 10, but the TSV switching circuit 30-1 related to a unidirectional signal transmitted from the core chip 20-2 is similarly configured. Regarding an implementation example of the TSV switching circuit 30-1 related to a bidirectional signal transmitted and received between the IF chip 10 and the core chip 20-1, differences from an implementation example in the case of the unidirectional signal will be mainly described. In addition, each of the TSV switching circuits 30-2, 30-3, and 30-4 has the same configuration as the TSV switching circuit 30-1 shown in FIGS. 3 to 11.

FIG. 3 is a circuit diagram showing the first implementation example of the TSV switching circuit included in the memory device according to the first embodiment. FIG. 3 shows the TSV switching circuit 30-1 related to a 1-bit signal SIG transmitted from the IF chip 10 and a part of the TSV switching circuit 30-2.

As shown in FIG. 3, the IF chip 10 includes an internal circuit C0, and the core chip 20-1 includes internal circuits C1 and C2. Furthermore, regarding the signal SIG, the TSV switching circuit 30-1 includes a default via dV1, a redundant via rV1, and switches dSW1 and rSW1 in the core chip 20-1. The TSV switching circuit 30-2 includes a default via dV2 and a redundant via rV2 in the core chip 20-2. Regarding the signal SIG transmitted from the internal circuit C0 of the IF chip 10, the internal circuit C0 of the IF chip 10 and the internal circuit C1 of the core chip 20-1 are connected through the TSV switching circuit 30-1 and the interconnect W1. In the core chip 20-1, the internal circuit C2 generates a signal SIG output to the core chip 20-2.

The default via dV1 has a first terminal to which the signal SIG is input, and a second terminal connected to a first terminal of the switch dSW1. The switch dSW1 has a second terminal connected to the interconnect W1.

The redundant via rV1 has a first terminal to which the signal SIG is input, and a second terminal connected to a first terminal of the switch rSW1. The switch rSW1 has a second terminal connected to the interconnect W1.

Each of the switches dSW1 and rSW1 is logically a two-terminal switch. In a case where the switch dSW1 is in an ON state, the switch rSW1 is in an OFF state. In a case where the switch dSW1 is in an OFF state, the switch rSW1 is in an ON state. The physical implementation of each of the switches dSW1 and rSW1 may be any that logically realizes a two-terminal switch. For example, in a case where the default via dV1 is used for transmitting a unidirectional signal, each switch may be implemented by a tri-state buffer in which one of the switches is exclusively turned on, or may be implemented by a bus switch or the like in which an on/off function is realized by a MOSFET. In a case where the default via dV1 is used for transmission and reception of a bidirectional signal, each switch may be implemented by four tri-state buffers in which only one switch is turned on at most. The same applies to other default vias and redundant vias described below.

With the above configuration, in a case where the switch dSW1 is in the ON state, the signal SIG can be communicated between the IF chip 10 and the core chip 20-1 through the default via dV1 and not through the redundant via rV1. In addition, in a case where the switch rSW1 is in the ON state, the signal SIG can be communicated between the IF chip 10 and the core chip 20-1 through the redundant via rV1 and not through the default via dV1.

As described above, in the implementation example of the TSV switching circuit 30-1 related to a unidirectional signal transmitted from the IF chip 10, the internal circuit C0 of the IF chip 10 and the internal circuit C1 of the core chip 20-1 function as a transmission circuit and a reception circuit, respectively. In the implementation example of the TSV switching circuit 30-1 related to a unidirectional signal transmitted from the core chip 20-1, the internal circuit C0 of the IF chip 10 and the internal circuit C1 of the core chip 20-1 function as a reception circuit and a transmission circuit with a tri-state buffer, respectively. In the implementation example of the TSV switching circuit 30-1 related to a bidirectional signal transmitted and received between the IF chip 10 and the core chip 20-1, the internal circuit C0 of the IF chip 10 and the internal circuit C1 of the core chip 20-1 function as a transmission/reception circuit with a tri-state buffer and a transmission/reception circuit with a tri-state buffer, respectively.

FIG. 4 is a circuit diagram showing a second implementation example of the TSV switching circuit included in the memory device according to the first embodiment. As shown in FIG. 4, the core chip 20-1 includes the internal circuits C1 and C2. The TSV switching circuit 30-1 includes inverters IV1 and IV2, an AND circuit AND1, and a NAND circuit NAND1 in the IF chip 10. The TSV switching circuit 30-1 includes the default via dV1, the redundant via rV1, a control via cV1, an inverter IV3, and NAND circuits NAND2, NAND3, and NAND4 in the core chip 20-1. In addition, the TSV switching circuit 30-2 includes inverters IV4 and IV5, an AND circuit AND2, and a NAND circuit NAND5 in the core chip 20-1. The TSV switching circuit 30-2 includes the default via dV2, the redundant via rV2, and a control via cV2 in the core chip 20-2.

A signal SEL is a 1-bit control signal supplied from the fuse circuit 17. The signal SEL is used for via switching related to the signal SIG in the TSV switching circuits 30-1, 30-2, 30-3, and 30-4. The signal SEL is supplied to the core chip 20-1 through the control via cV1, and is further supplied to the core chip 20-2 through the control via cV2. In a case where the signal SEL is “0”, the default via dV1 is selected, and in a case where the signal SEL is “1”, the redundant via rV1 is selected. In a case where the signal SEL is “0”, the default via dV2 is selected, and in a case where the signal SEL is “1”, the redundant via rV2 is selected.

The inverter IV1 includes an input terminal to which the signal SEL is input, and an output terminal that outputs a NOT operation result of the input signal.

The AND circuit AND1 includes a first input terminal to which the signal SIG is input, a second input terminal connected to the output terminal of the inverter IV1, and an output terminal that outputs an AND operation result of the input signals to the first terminal of the default via dV1.

The NAND circuit NAND1 includes a first input terminal to which the signal SIG is input, a second input terminal to which the signal SEL is input, and an output terminal that outputs a NAND operation result of the input signals.

The inverter IV2 includes an input terminal connected to the output terminal of the NAND circuit NAND1, and an output terminal that outputs a NOT operation result of the input signal to the first terminal of the redundant via rV1.

The inverter IV3 includes an input terminal to which the signal SEL is input through the control via cV1, and an output terminal that outputs a NOT operation result of the input signal.

The NAND circuit NAND2 includes a first input terminal connected to the second terminal of the default via dV1, a second input terminal connected to the output terminal of the inverter IV3, and an output terminal that outputs a NAND operation result of the input signals.

The NAND circuit NAND3 includes a first input terminal connected to the second terminal of the redundant via rV1, a second input terminal to which the signal SEL is input through the control via cV1, and an output terminal that outputs a NAND operation result of the input signals.

The NAND circuit NAND4 includes a first input terminal connected to the output terminal of the NAND circuit NAND2, a second input terminal connected to the output terminal of the NAND circuit NAND3, and an output terminal that outputs a NAND operation result of the input signals to the interconnect W1.

The internal circuit C1 receives the signal SIG from the IF chip 10 through the interconnect W1. The internal circuit C1 uses the signal SIG for internal processing in the core chip 20-1.

The internal circuit C2 is a circuit that generates a signal SIG in the core chip 20-1. The internal circuit C2 outputs the signal SIG to the AND circuit AND2 and the NAND circuit NAND5.

The inverter IV4 includes an input terminal to which the signal SEL is input through the control via cV1, and an output terminal that outputs a NOT operation result of the input signal.

The AND circuit AND2 includes a first input terminal to which the signal SIG is input from the internal circuit C2, a second input terminal connected to the output terminal of the inverter IV4, and an output terminal that outputs an AND operation result of the input signals to the first terminal of the default via dV2.

The NAND circuit NAND5 includes a first input terminal to which the signal SIG is input from the internal circuit C2, a second input terminal to which the signal SEL is input through the control via cV1, and an output terminal that outputs a NAND operation result of the input signals.

The inverter IV5 includes an input terminal connected to the output terminal of the NAND circuit NAND5, and an output terminal that outputs a NOT operation result of the input signal to the first terminal of the redundant via rV2.

Note that FIG. 4 is a circuit diagram showing an implementation example of a select circuit used for a unidirectional signal output from the IF chip 10, and shows a select circuit where the signal SIG is output from the internal circuit C0 of the IF chip 10 and input to the internal circuit C1 of the core chip 20-1. In a case where the signal SIG is a bidirectional signal, a tri-state buffer is mounted between the default via and the last stage of the transmission circuit of each of the internal circuit C0 of the IF chip 10 and the internal circuit C1 of the core chip 20-1. The same applies to the redundant via.

FIG. 5 is a diagram showing an example of a relationship among signals transmitted by the TSV switching circuit according to the first embodiment. In FIG. 5, values of the default via dV1, the redundant via rV1, the output terminals of the NAND circuits NAND2 and NAND3, and the interconnect W1, for each set of values of the signals SEL and SIG are shown.

<Case where Default Via dV1 is Selected>

First, a case where the default via dV1 is selected will be described. In this case, the fuse circuit 17 outputs “0” as the signal SEL.

In this case, “1” is input to the second input terminal of the AND circuit AND1 and the second input terminal of the NAND circuit NAND2. Therefore, the value in the default via dV1 is a value corresponding to the signal SIG. In addition, the value at the output terminal of the NAND circuit NAND2 is a value obtained by inverting the value (that is, the signal SIG) in the default via dV1.

On the other hand, “0” is input to the second input terminal of the NAND circuit NAND1 and the second input terminal of the NAND circuit NAND3. Therefore, the value in the redundant via rV1 is “0” regardless of the value of the signal SIG. In addition, the value at the output terminal of the NAND circuit NAND3 is “1” regardless of the value at the redundant via rV1 (that is, even if the value in the redundant via rV1 changes to “1” due to some abnormality).

Therefore, in a case where the default via dV1 functions correctly, the value at the output terminal of the NAND circuit NAND4, that is, the value in the interconnect W1 becomes a value corresponding to the signal SIG regardless of whether the redundant via rV1 functions correctly.

<Case where Redundant Via rV1 is Selected>

Next, a case where the redundant via rV1 is selected will be described. In this case, the fuse circuit 17 outputs “1” as the signal SEL.

In this case, “0” is input to the second input terminal of the AND circuit AND1 and the second input terminal of the NAND circuit NAND2. Therefore, the value at the default via dV1 is “0” regardless of the value of the signal SIG. In addition, the value at the output terminal of the NAND circuit NAND2 is “1” regardless of the value at the default via dV1 (that is, even if the value in the default via dV1 changes to “1” due to some abnormality).

On the other hand, “1” is input to the second input terminal of the NAND circuit NAND1 and the second input terminal of the NAND circuit NAND3. Therefore, the value at the redundant via rV1 is a value corresponding to the signal SIG. In addition, the value at the output terminal of the NAND circuit NAND3 is a value obtained by inverting the value in the redundant via rV1 (that is, the signal SIG).

Therefore, in a case where the redundant via rV1 functions correctly, the value at the output terminal of the NAND circuit NAND4, that is, the value in the interconnect W1 becomes a value corresponding to the signal SIG regardless of whether the default via dV1 functions correctly.

With the above configuration, in a case where the signal SEL is “0”, regardless of whether the redundant via rV1 functions correctly, the signal SIG can be communicated between the IF chip 10 and the core chip 20-1 through the default via dV1. Furthermore, in a case where the signal SEL is “1”, regardless of whether the default via dV1 functions correctly, the signal SIG can be communicated between the IF chip 10 and the core chip 20-1 through the redundant via rV1.

### 1.2 Effects According to First Embodiment

According to the first embodiment, the TSV switching circuit 30-1 is configured, between the IF chip 10 and the core chip 20-1, to switch between a state of communicating the signal SIG through the default via dV and a state of communicating the signal SIG through the redundant via rV.

For example, in the first implementation example, communication through the default via dV is enabled by turning on the switch dSW1 and turning off the switch rSW1. By turning off the switch dSW1 and turning on the switch rSW1, communication through the redundant via rV becomes possible.

Furthermore, for example, in the second implementation example, by using the control signal SEL, it is possible to select which one of the default via dV and the redundant via rV is used for communication. With this configuration, even if the default via dV has a connection failure, the redundant via rV can be used. Therefore, chip failure can be avoided, and the yield of the memory device 5 can be improved.

### 1.3 Modifications of First Embodiment

Various modifications can be applied to the above-described first embodiment.

### 1.3.1 First Modification of First Embodiment

In the first embodiment described above, a case where one redundant via is assigned to one default via has been described, but the present embodiment is not limited thereto. For example, one redundant via may be assigned to a plurality of default vias. Hereinafter, a configuration different from that of the first embodiment will be mainly described. Description of configurations equivalent to those of the first embodiment will be omitted as appropriate.

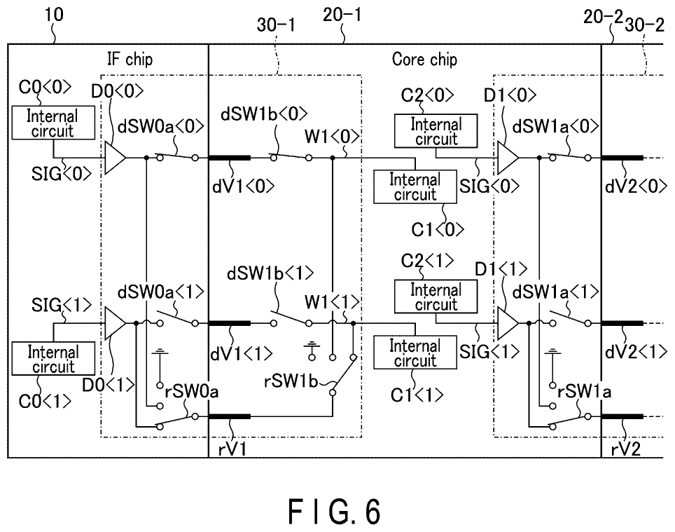

FIG. 6 is a circuit diagram showing a first implementation example of a TSV switching circuit included in a memory device according to a first modification of the first embodiment. The configuration shown in FIG. 6 corresponds to the configuration in the first embodiment shown in FIG. 3.

As shown in FIG. 6, the IF chip 10 includes internal circuits C0<0> and C0<1>, and the core chip 20-1 includes internal circuits C1<0>, C1<1>, C2<0>, and C2<1>. Further, regarding signals SIG<0> and SIG<1>, the TSV switching circuit 30-1 includes drivers D0<0> and D0<1> and switches dSW0a<0>, dSW0a<1>, and rSW0a in the IF chip 10. The TSV switching circuit 30-1 includes default vias dV1<0> and dV1<1>, a redundant via rV1, and switches dSW1b<0>, dSW1b<1>, and rSW1b in the core chip 20-1. The default via dV1<0> is an example of a first via. The default via dV1<1> is an example of a second via. The redundant via rV1 is an example of a third via. The switch rSW0a is an example of a first switch. The switch dSW1b<0> is an example of a second switch. The switch dSW1b<1> is an example of a third switch. The switch rSW1b is an example of a fourth switch.

The TSV switching circuit 30-2 includes drivers D1<0> and D1<1>, and switches dSW1a<0>, dSW1a<1>, and rSW1a in the core chip 20-1. The TSV switching circuit 30-2 includes default vias dV2<0> and dV2<1> and a redundant via rV2 in the core chip 20-2. Regarding the signal SIG<0> transmitted from the internal circuit C0<0> of the IF chip 10, the internal circuit C0<0> of the IF chip 10 and the internal circuit C1<0> of the core chip 20-1 are connected through the TSV switching circuit 30-1 and the interconnect W1<0>. Regarding the signal SIG<1> transmitted from the internal circuit C0<1> of the IF chip 10, the internal circuit C0<1> of the IF chip 10 and the internal circuit C1<1> of the core chip 20-1 are connected through the TSV switching circuit 30-1 and the interconnect W1<1>. The internal circuits C1<0> and C1<1> of the core chip 20-1 are connected to the interconnects W1<0> and W1<1>, respectively.

The driver D0<0> has an input terminal to which the signal SIG<0> is input, and an output terminal. The driver D0<1> has an input terminal to which the signal SIG<1> is input, and an output terminal. In a case where the signals SIG<0> and SIG<1> are bidirectional signals, each of the driver D0<0> and the driver D0<1> is implemented with a tri-state buffer.

Each of the switches dSW0a<0> and dSW0a<1> is a two-terminal switch. The switch dSW0a<0> has a first terminal connected to the output terminal of the driver D0<0>, and a second terminal connected to a first terminal of the default via dV1<0>. The switch dSW0a<1> has a first terminal connected to the output terminal of the driver D0<1>, and a second terminal connected to a first terminal of the default via dV1<1>.

The switch rSW0a is a four-terminal switch. The switch rSW0a has a first terminal connected to the output terminal of the driver D0<0>, a second terminal connected to the output terminal of the driver D0<1>, a third terminal connected to a first terminal of the redundant via rV1, and a fourth terminal grounded. In a case where the switch rSW0a is in the ON state, the third terminal is in a connected state with either the first terminal or the second terminal. In a case where the switch rSW0a is in the OFF state, the third terminal is connected to the fourth terminal.

Each of the switches dSW1b<0> and dSW1b<1> is a two-terminal switch. The switch dSW1b<0> has a first terminal connected to a second terminal of the default via dV1<0> and a second terminal connected to the interconnect W1<0>. The switch dSW1b<1> has a first terminal connected to a second terminal of the default via dV1<1> and a second terminal connected to the interconnect W1<1>.

The switch rSW1b is a four-terminal switch. The switch rSW1b has a first terminal connected to a second terminal of the redundant via rV1, a second terminal connected to the interconnect W1<0>, a third terminal connected to the interconnect W1<1>, and a fourth terminal grounded. In a case where the switch rSW1b is in the ON state, the first terminal is connected to either the second terminal or the third terminal. In a case where the switch rSW1b is in the OFF state, the first terminal is connected to the fourth terminal.

The driver D1<0> has an input terminal connected to an output terminal of the internal circuit C2<0>, and an output terminal. The driver D1<1> has an input terminal connected to an output terminal of the internal circuit C2<1>, and an output terminal. In a case where the signals SIG<0> and SIG<1> are bidirectional signals, each of the driver D1<0> and the driver D1<1> is implemented with a tri-state buffer.

The internal circuit C1<0> receives the signal SIG<0> from the internal circuit C0<0> of the IF chip 10 through the interconnect W1<0>. The internal circuit C1<1> receives the signal SIG<1> from the internal circuit C0<1> of the IF chip 10 through the interconnect W1<1>. The internal circuits C1<0> and C1<1> use the signals SIG<0> and SIG<1> for internal processing in the core chip 20-1, respectively.

The internal circuits C2<0> and C2<1> are circuits that generate signals SIG<0> and SIG<1> in the core chip 20-1, respectively. The internal circuit C2<0> outputs the signal SIG<0> to the input terminal of the driver D1<0>. The internal circuit C2<1> outputs the signal SIG<1> to the input terminal of the driver D1<1>.

Each of the switches dSW1a<0> and dSW1a<1> is a two-terminal switch. The switch dSW1a<0> has a first terminal connected to the output terminal of the driver D1<0> and a second terminal connected to a first terminal of the default via dV2<0>. The switch dSW1a<1> has a first terminal connected to the output terminal of the driver D1<1> and a second terminal connected to a first terminal of the default via dV2<1>.

The switch rSW1a is a four-terminal switch. The switch rSW1a has a first terminal connected to the output terminal of the driver D1<0>, a second terminal connected to the output terminal of the driver D1<1>, a third terminal connected to a first terminal of the redundant via rV2, and a fourth terminal grounded. In a case where the switch rSW1a is in the ON state, the third terminal is in a connected state with either the first terminal or the second terminal. In a case where the switch rSW1a is in the OFF state, the third terminal is connected to the fourth terminal.

FIG. 6 shows a case where the signal SIG<0> generated in the internal circuit C0<0> is transmitted to the interconnect W1<0> through the default via dV1<0>, the signal SIG<1> generated in the internal circuit C0<1> is transmitted to the interconnect W1<1> through the redundant via rV1, the signal SIG<0> generated in the internal circuit C2<0> is transmitted to the default via dV2<0>, and the signal SIG<1> generated in the internal circuit C2<1> is transmitted to the redundant via rV2. In this case, the switches dSW0a<0>, dSW1b<0>, and dSW1a<0> are turned on. The switches dSW0a<1>, dSW1b<1>, and dSW1a<1> are turned off. In each of the switches rSW0a and rSW1a, the second terminal and the third terminal are connected. In the switch rSW1b, the first terminal and the third terminal are connected. Note that the drivers D0<0> and D0<1> are turned on in a case where the signals SIG<0> and SIG<1> are output from the IF chip 10, and are turned off otherwise. The drivers D1<0> and D1<1> are turned on in a case where the signals SIG<0> and SIG<1> are output from the core chip 20-1, and are turned off otherwise.

On the other hand, in a case where the signal SIG<0> generated in the internal circuit C0<0> is transmitted to the interconnect W1<0> through the redundant via rV1, the signal SIG<1> generated in the internal circuit C0<1> is transmitted to the interconnect W1<1> through the default via dV1<1>, the signal SIG<0> generated in the internal circuit C2<0> is transmitted to the redundant via rV2, and the signal SIG<1> generated in the internal circuit C2<1> is transmitted to the default via dV2<1>, each switch is in the following state. In other words, the switches dSW0a<0>, dSW1b<0>, and dSW1a<0> are turned off. The switches dSW0a<1>, dSW1b<1>, and dSW1a<1> are turned on. In each of the switches rSW0a and rSW1a, the first terminal and the third terminal are connected. In the switch rSW1b, the first terminal and the second terminal are connected. Note that the drivers D0<0> and D0<1> are turned on in a case where the signals SIG<0> and SIG<1> are output from the IF chip 10, and are turned off otherwise. The drivers D1<0> and D1<1> are turned on in a case where the signals SIG<0> and SIG<1> are output from the core chip 20-1, and are turned off otherwise.

With the above configuration, any one of the communication paths of the signals SIG<0> and SIG<1> can be switched to one redundant via rV1.

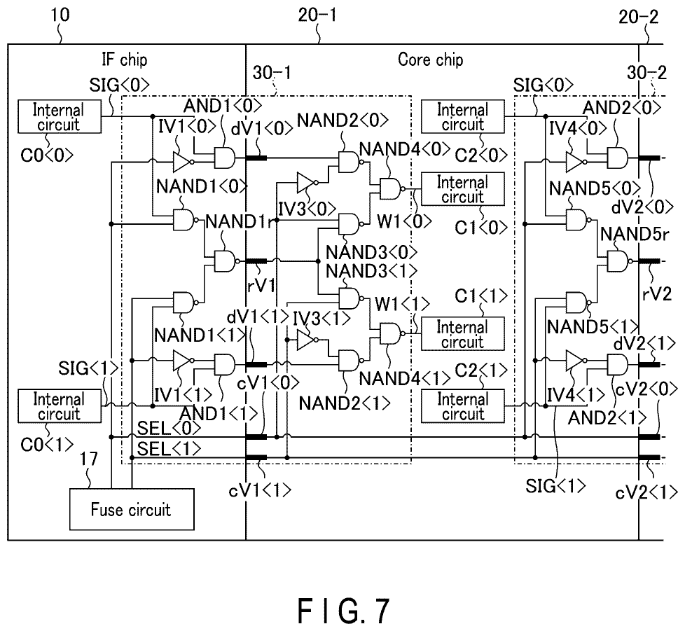

FIG. 7 is a circuit diagram showing a second implementation example of the TSV switching circuit included in the memory device according to the first modification of the first embodiment. The configuration shown in FIG. 7 corresponds to the configuration in the first embodiment shown in FIG. 4.

As shown in FIG. 7, the core chip 20-1 includes internal circuits C1<0>, C1<1>, C2<0>, and C2<1>. The TSV switching circuit 30-1 includes inverters IV1<0> and IV1<1>, AND circuits AND1<0> and AND1<1>, and NAND circuits NAND1<0>, NAND1<1>, and NAND1r in the IF chip 10. The TSV switching circuit 30-1 includes default vias dV1<0> and dV1<1>, a redundant via rV1, control vias cV1<0> and cV1<1>, inverters IV3<0> and IV3<1>, and NAND circuits NAND2<0>, NAND2<1>, NAND3<0>, NAND3<1>, NAND4<0>, and NAND4<1> in the core chip 20-1. The TSV switching circuit 30-2 includes inverters IV4<0> and IV4<1>, AND circuits AND2<0> and AND2<1>, and NAND circuits NAND5<0>, NAND5<1>, and NAND5r in the core chip 20-1. The TSV switching circuit 30-2 includes default vias dV2<0> and dV2<1>, a redundant via rV2, and control vias cV2<0> and cV2<1> in the core chip 20-2.

The inverter IV1<0> is an example of a first inverter. The inverter IV1<1> is an example of a second inverter. The AND circuit AND1<0> is an example of a first AND circuit. The AND circuit AND1<1> is an example of a second AND circuit. The NAND circuit NAND1<0> is an example of a first NAND circuit. The NAND circuit NAND1<1> is an example of a second NAND circuit. The NAND circuit NAND1r is an example of a third NAND circuit. The inverter IV3<0> is an example of a third inverter. The inverter IV3<1> is an example of a fourth inverter. The NAND circuit NAND2<0> is an example of a fourth NAND circuit. The NAND circuit NAND2<1> is an example of a fifth NAND circuit. The NAND circuit NAND3<0> is an example of a sixth NAND circuit. The NAND circuit NAND3<1> is an example of a seventh NAND circuit. The NAND circuit NAND4<0> is an example of an eighth NAND circuit. The NAND circuit NAND4<1> is an example of a ninth NAND circuit.

Each of signals SEL<0> and SEL<1> is a 1-bit control signal supplied from the fuse circuit 17. The signals SEL<0> and SEL<1> are used for via switching for the signals SIG<0> and SIG<1> in the TSV switching circuits 30-1, 30-2, 30-3, and 30-4, respectively. The signal SEL<0> is supplied to the core chip 20-1 through the control via cV1<0>, and further supplied to the core chip 20-2 through the control via cV2<0>. The signal SEL<1> is supplied to the core chip 20-1 through the control via cV1<1>, and further supplied to the core chip 20-2 through the control via cV2<1>. In a case where the signal SEL<0> is “0”, the default via is selected for the signal SIG<0>, and in a case where the signal SEL<0> is “1”, the redundant via is selected for the signal SIG<0>. In a case where the signal SEL<1> is “0”, the default via is selected for the signal SIG<1>, and in a case where the signal SEL<1> is “1”, the redundant via is selected for the signal SIG<1>. In the case of the configuration shown in FIG. 7, both the signals SEL<0> and SEL<1> are controlled so as not to be “1” at the same time.

The inverter IV1<0> includes an input terminal to which the signal SEL<0> is input, and an output terminal that outputs a NOT operation result of the input signal. The inverter IV1<1> includes an input terminal to which the signal SEL<1> is input, and an output terminal that outputs a NOT operation result of the input signal.

The AND circuit AND1<0> includes a first input terminal to which the signal SIG<0> is input, a second input terminal connected to the output terminal of the inverter IV1<0>, and an output terminal that outputs an AND operation result of the input signals to a first terminal of the default via dV1<0>. The AND circuit AND1<1> includes a first input terminal to which the signal SIG<1> is input, a second input terminal connected to the output terminal of the inverter IV1<1>, and an output terminal that outputs an AND operation result of the input signals to a first terminal of the default via dV1<1>.

The NAND circuit NAND1<0> includes a first input terminal to which the signal SIG<0> is input, a second input terminal to which the signal SEL<0> is input, and an output terminal that outputs a NAND operation result of the input signals. The NAND circuit NAND1<1> includes a first input terminal to which the signal SIG<1> is input, a second input terminal to which the signal SEL<1> is input, and an output terminal that outputs a NAND operation result of the input signals.

The NAND circuit NAND1r includes a first input terminal connected to the output terminal of the NAND circuit NAND1<0>, a second input terminal connected to the output terminal of the NAND circuit NAND1<1>, and an output terminal that outputs a NAND operation result of the input signals to a first terminal of the redundant via rV1.

The inverter IV3<0> includes an input terminal to which the signal SEL<0> is input through the control via cV1<0>, and an output terminal that outputs a NOT operation result of the input signal. The inverter IV3<1> includes an input terminal to which the signal SEL<1> is input through the control via cV1<1>, and an output terminal that outputs a NOT operation result of the input signal.

The NAND circuit NAND2<0> includes a first input terminal connected to a second terminal of the default via dV1<0>, a second input terminal connected to the output terminal of the inverter IV3<0>, and an output terminal that outputs a NAND operation result of the input signals. The NAND circuit NAND2<1> includes a first input terminal connected to a second terminal of the default via dV1<1>, a second input terminal connected to the output terminal of the inverter IV3<1>, and an output terminal that outputs a NAND operation result of the input signals.

The NAND circuit NAND3<0> includes a first input terminal connected to the second terminal of the redundant via rV1, a second input terminal to which the signal SEL<0> is input through the control via cV1<0>, and an output terminal that outputs a NAND operation result of the input signals. The NAND circuit NAND3<1> includes a first input terminal connected to the second terminal of the redundant via rV1, a second input terminal to which the signal SEL<1> is input through the control via cV1<1>, and an output terminal that outputs a NAND operation result of the input signals.

The NAND circuit NAND4<0> includes a first input terminal connected to the output terminal of the NAND circuit NAND2<0>, a second input terminal connected to the output terminal of the NAND circuit NAND3<0>, and an output terminal that outputs a NAND operation result of the input signals to the interconnect W1<0>. The NAND circuit NAND4<1> includes a first input terminal connected to the output terminal of the NAND circuit NAND2<1>, a second input terminal connected to the output terminal of the NAND circuit NAND3<1>, and an output terminal that outputs a NAND operation result of the input signals to the interconnect W1<1>.

The internal circuit C1<0> receives the signal SIG<0> from the IF chip 10 through the interconnect W1<0>. The internal circuit C1<1> receives the signal SIG<1> from the IF chip 10 through the interconnects W1<1>. The internal circuits C1<0> and C1<1> use the signals SIG<0> and SIG<1> for internal processing in the core chip 20-1, respectively.

The internal circuits C2<0> and C2<1> are circuits that generate signals SIG<0> and SIG<1> in the core chip 20-1, respectively. The internal circuit C2<0> outputs the signal SIG<0> to the AND circuit AND2<0> and the NAND circuit NAND5<0>. The internal circuit C2<1> outputs the signal SIG<1> to the AND circuit AND2<1> and the NAND circuit NAND5<1>.

The inverter IV4<0> includes an input terminal to which the signal SEL<0> is input through the control via cV1<0>, and an output terminal that outputs a NOT operation result of the input signal. The inverter IV4<1> includes an input terminal to which the signal SEL<1> is input through the control via cV1<1>, and an output terminal that outputs a NOT operation result of the input signal.

The AND circuit AND2<0> includes a first input terminal to which the signal SIG<0> is input from the internal circuit C2<0>, a second input terminal connected to the output terminal of the inverter IV4<0>, and an output terminal that outputs an AND operation result of the input signals to a first terminal of the default via dV2<0>. The AND circuit AND2<1> includes a first input terminal to which the signal SIG<1> is input from the internal circuit C2<1>, a second input terminal connected to the output terminal of the inverter IV4<1>, and an output terminal that outputs an AND operation result of the input signals to a first terminal of the default via dV2<1>.

The NAND circuit NAND5<0> includes a first input terminal to which the signal SIG<0> is input from the internal circuit C2<0>, a second input terminal to which the signal SEL<0> is input through the control via cV1<0>, and an output terminal that outputs a NAND operation result of the input signals. The NAND circuit NAND5<1> includes a first input terminal to which the signal SIG<1> is input from the internal circuit C2<1>, a second input terminal to which the signal SEL<1> is input through the control via cV1<1>, and an output terminal that outputs a NAND operation result of the input signals.

The NAND circuit NAND5r includes a first input terminal connected to the output terminal of the NAND circuit NAND5<0>, a second input terminal connected to the output terminal of the NAND circuit NAND5<1>, and an output terminal that outputs a NAND operation result of the input signals to the first terminal of the redundant via rV2.

With the above configuration, in a case where both the signals SEL<0> and SEL<1> are “0”, the signals SIG<0> and SIG<1> can be communicated through the default vias dV1<0> and dV1<1>, respectively, regardless of whether the redundant via rV1 functions correctly. In a case where the signal SEL<0> is “1” and the signal SEL<1> is “0”, the signal SIG<1> can be communicated through the default via dV1<1> while the signal SIG<0> is communicated through the redundant via rV1, regardless of whether the default via dV1<0> functions correctly. In a case where the signal SEL<0> is “0” and the signal SEL<1> is “1”, the signal SIG<0> can be communicated through the default via dV1<0> while the signal SIG<1> is communicated through the redundant via rV1, regardless of whether the default via dV1<1> functions correctly.

Note that, in the examples of FIGS. 6 and 7, a case where one redundant via is allocated to two default vias has been described. However, the number of default vias may be three or more, and the number of redundant vias may be two or more. Note that, although the second implementation example shown in FIG. 7 has a one-hot configuration in which at most one of the control signals SEL<1:0> becomes “1”, another implementation method may be used. For example, the control signals SEL<1:0> may include an enable signal EN and an encoded selection signal. The same applies to subsequent implementation examples.

According to the first modification of the first embodiment, the TSV switching circuit 30-1 is configured to switch between a first state in which the signal SIG<1> is communicated through the default via dV<1> while the signal SIG<0> is communicated through the default via dV<0>, a second state in which the signal SIG<1> is communicated through the default via dV<1> while the signal SIG<0> is communicated through the redundant via rV, and a third state in which the signal SIG<1> is communicated through the redundant via rV while the signal SIG<0> is communicated through the default via dV<0>, between the IF chip 10 and the core chip 20-1.

For example, in the first implementation example, the first state is realized by turning on the switches dSW0a<0>, dSW0a<1>, dSW1b<0>, and dSW1b<1>, connecting the third terminal and the fourth terminal of the switch rSW0a, and turning off the switch rSW1b. The second state is realized by turning on the switches dSW0a<1> and dSW1b<1>, turning off the switches dSW0a<0> and dSW1b<0>, connecting the first terminal and the third terminal of the switch rSW0a, and connecting the first terminal and the second terminal of the switch rSW1b. The third state is realized by turning on the switches dSW0a<0> and dSW1b<0>, turning off the switches dSW0a<1> and dSW1b<1>, connecting the second terminal and the third terminal of the switch rSW0a, and connecting the first terminal and the third terminal of the switch rSW1b.

Furthermore, for example, in the second implementation example, the first state is realized by setting both the signals SEL<0> and SEL<1> to “0”. The second state is realized by setting the signals SEL<0> and SEL<1> to “1” and “0”, respectively. The third state is realized by setting the signals SEL<0> and SEL<1> to “0” and “1”, respectively.

As a result, the redundant via rV can be used as an alternative to any of the default vias dV<0> and dV<1>.

### 1.3.2 Second Modification of First Embodiment

In the first modification of the first embodiment described above, the case where the signal having passed through one of the default via and the redundant via is transmitted to the interconnects in the core chip has been described, but the present embodiment is not limited thereto. Hereinafter, a configuration different from that of the first modification of the first embodiment will be mainly described. Description of configurations equivalent to those of the first modification of the first embodiment will be omitted as appropriate.

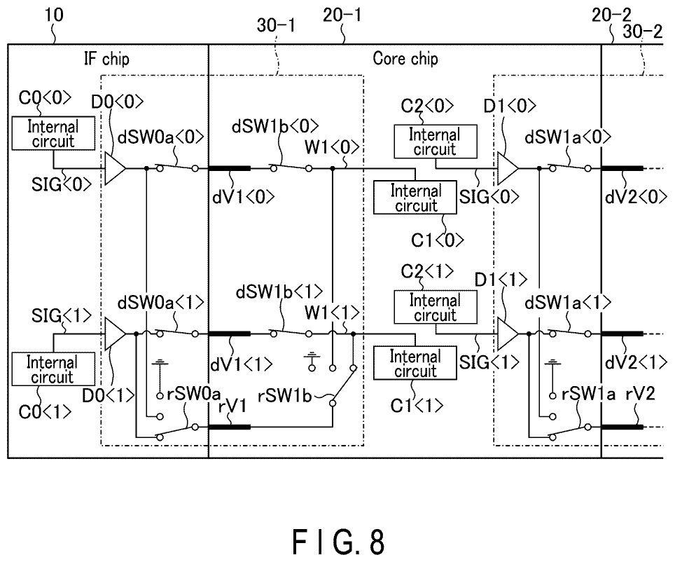

FIG. 8 is a circuit diagram showing a first implementation example of a TSV switching circuit included in a memory device according to a second modification of the first embodiment. The configuration shown in FIG. 8 corresponds to the configuration in the first modification of the first embodiment shown in FIG. 6.

As shown in FIG. 8, the first implementation example of the TSV switching circuit 30-1 in the second modification of the first embodiment is equivalent to the first implementation example in the first modification of the first embodiment. In the circuit configuration, FIG. 8 shows a case where the signal SIG<0> generated in the internal circuit C0<0> is transmitted to the interconnect W1<0> through the default via dV1<0>, the signal SIG<1> generated in the internal circuit C0<1> is transmitted to the interconnect W1<1> through both the default via dV1<1> and the redundant via rV1, the signal SIG<0> generated in the internal circuit C2<0> is transmitted to the default via dV2<0>, and the signal SIG<1> generated in the internal circuit C2<1> is transmitted to both the default via dV2<1> and the redundant via rV2. In this case, the switches dSW0a<0>, dSW0a<1>, dSW1b<0>, dSW1b<1>, dSW1a<0>, and dSW1a<1> are turned on. In each of the switches rSW0a and rSW1a, the second terminal and the third terminal are connected. In the switch rSW1b, the first terminal and the third terminal are connected. Note that the drivers D0<0> and D0<1> are turned on in a case where the signals SIG<0> and SIG<1> are output from the IF chip 10, and are turned off otherwise. The drivers D1<0> and D1<1> are turned on in a case where the signals SIG<0> and SIG<1> are output from the core chip 20-1, and are turned off otherwise.

On the other hand, in a case where the signal SIG<0> generated in the internal circuit C0<0> is transmitted to the interconnect W1<0> through both the default via dV1<0> and the redundant via rV1, the signal SIG<1> generated in the internal circuit C0<1> is transmitted to the interconnect W1<1> through the default via dV1<1>, the signal SIG<0> generated in the internal circuit C2<0> is transmitted to both the default via dV2<0> and the redundant via rV2, and the signal SIG<1> generated in the internal circuit C2<1> is transmitted to the default via dV2<1>, each switch enters the following state. That is, the switches dSW0a<0>, dSW0a<1>, dSW1b<0>, dSW1b<1>, dSW1a<0>, and dSW1a<1> are turned on. In each of the switches rSW0a and rSW1a, the first terminal and the third terminal are connected. In the switch rSW1b, the first terminal and the second terminal are connected. Note that the drivers D0<0> and D0<1> are turned on in a case where the signals SIG<0> and SIG<1> are output from the IF chip 10, and are turned off otherwise. The drivers D1<0> and D1<1> are turned on in a case where the signals SIG<0> and SIG<1> are output from the core chip 20-1, and are turned off otherwise.

With the above configuration, one redundant via rV1 and any one of the two default vias dV1<0> and dV1<1> can be simultaneously used for transmission of one signal SIG.

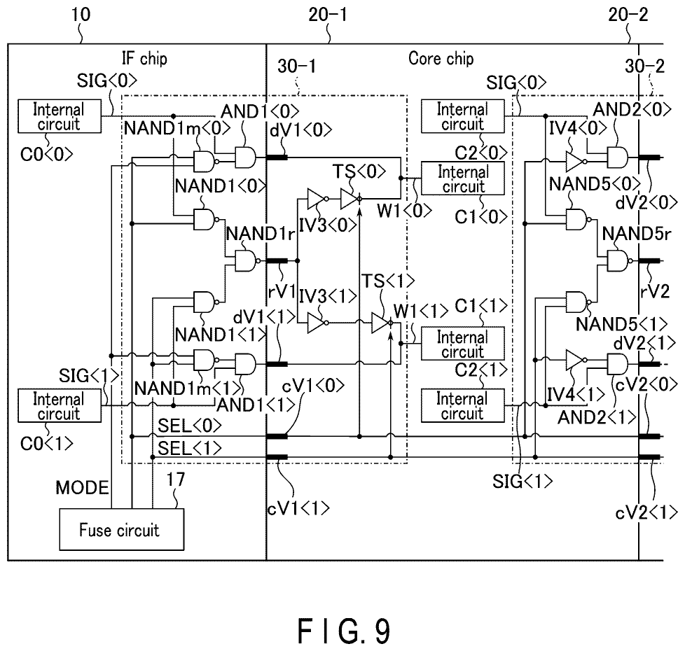

FIG. 9 is a circuit diagram showing a second implementation example of the TSV switching circuit included in the memory device according to the second modification of the first embodiment. The configuration shown in FIG. 9 corresponds to the configuration in the first modification of the first embodiment shown in FIG. 7.

As shown in FIG. 9, in the IF chip 10, the TSV switching circuit 30-1 according to the second modification of the first embodiment includes NAND circuits NAND1m<0> and NAND1m<1> instead of the inverters IV1<0> and IV1<1> of the TSV switching circuit 30-1 according to the first modification of the first embodiment. In the core chip 20-1, the TSV switching circuit 30-1 according to the second modification of the first embodiment includes tri-state buffers TS<0> and TS<1> instead of the NAND circuits NAND2<0>, NAND2<1>, NAND3<0>, NAND3<1>, NAND4<0>, and NAND4<1> of the TSV switching circuit 30-1 according to the first modification of the first embodiment. The NAND circuit NAND1m<0> is an example of a tenth NAND circuit. The NAND circuit NAND1m<1> is an example of an eleventh NAND circuit. The tri-state buffer TS<0> is an example of a first tri-state buffer. The tri-state buffer TS<1> is an example of a second tri-state buffer.

A signal MODE is a 1-bit control signal supplied from the fuse circuit 17. The signal MODE is a control signal used to select whether or not to share the redundant via and the default via for a certain signal SIG. In a case where the signal MODE is “0”, the redundant via and the default via are shared by the signal SIG corresponding to the signal SEL of “1”. Therefore, in a case where the signal MODE is “0”, one of the signals SEL<0> and SEL<1> becomes “1” (that is, the signals SEL<0> and SEL<1> are controlled so as not to be “0” at the same time or “1” at the same time). In addition, in a case where the signal MODE is “1”, one of the redundant via and the default via is used for all the signals SIG (that is, the signals SEL<0> and SEL<1> are controlled so as not to be “1” at the same time).

The NAND circuit NAND1m<0> has a first input terminal to which the signal SEL<0> is input, a second input terminal to which the signal MODE is input, and an output terminal connected to the second input terminal of the AND circuit AND1<0>. The NAND circuit NAND1m<1> has a first input terminal to which the signal SEL<1> is input, a second input terminal to which the signal MODE is input, and an output terminal connected to the second input terminal of the AND circuit AND1<1>.

The tri-state buffer TS<0> has an input terminal connected to the output terminal of the inverter IV3<0>, an output terminal connected to the interconnect W1<0>, and a control terminal to which the signal SEL<0> is input through the control via cV1<0>. In a case where the signal SEL<0> is “1”, the tri-state buffer TS<0> inverts a signal of the input terminal and conducts the signal to the output terminal. In a case where the signal SEL<0> is “0”, the tri-state buffer TS<0> insulates the input terminal and the output terminal.

The tri-state buffer TS<1> has an input terminal connected to the output terminal of the inverter IV3<1>, an output terminal connected to the interconnect W1<1>, and a control terminal to which the signal SEL<1> is input through the control via cV1<1>. In a case where the signal SEL<1> is “1”, the tri-state buffer TS<1> inverts a signal of the input terminal and conducts the signal to the output terminal. In a case where the signal SEL<1> is “0”, the tri-state buffer TS<1> insulates the input terminal and the output terminal.

The internal circuit C1<0> is connected to the second terminal of the default via dV1<0> and the output terminal of the tri-state buffer TS<0> through the interconnect W1<0>. The internal circuit C1<0> uses the signal SIG<0> received from the IF chip 10 through the interconnect W1<0> for the internal processing in the core chip 20-1. The internal circuit C1<1> is connected to the second terminal of the default via dV1<1> and the output terminal of the tri-state buffer TS<1> through the interconnect W1<1>. The internal circuit C1<1> uses the signal SIG<1> received from the IF chip 10 through the interconnect W1<1> for the internal processing in the core chip 20-1.

With the above configuration, in addition to a mode (MODE=“1”) in which the default via is switched to the redundant via, the signal SIG can be transmitted in a mode (MODE=“0”) in which the default via and the redundant via are shared.

According to the second modification of the first embodiment, the TSV switching circuit 30-1 is configured to switch between a fourth state in which the signal SIG<1> is communicated through the default via dV<1> while the signal SIG<0> is communicated through the default via dV<0> and the redundant via rV, and a fifth state in which the signal SIG<1> is communicated through the default via dV<1> and the redundant via rV while the signal SIG<0> is communicated through the default via dV<0>, in addition to the first state, the second state, and the third state.

For example, in the first implementation example, the fourth state is realized by turning on the switches dSW0a<0>, dSW0a<1>, dSW1b<0>, and dSW1b<1>, connecting the first terminal and the third terminal of the switch rSW0a, and connecting the first terminal and the second terminal of the switch rSW1b. The fifth state is realized by turning on the switches dSW0a<0>, dSW0a<1>, dSW1b<0>, and dSW1b<1>, connecting the second terminal and the third terminal of the switch rSW0a, and connecting the first terminal and the third terminal of the switch rSW1b.

Furthermore, for example, in the second implementation example, the first state is realized by setting the signals SEL<0>, SEL<1>, and MODE to “0”, “0”, and “1”, respectively. The second state is realized by setting the signals SEL<0>, SEL<1>, and MODE to “1”, “0”, and “1”, respectively. The third state is realized by setting the signals SEL<0>, SEL<1>, and MODE to “0”, “1”, and “1”, respectively. The fourth state is realized by setting the signals SEL<0>, SEL<1>, and MODE to “1”, “0”, and “0”, respectively. The fifth state is realized by setting the signals SEL<0>, SEL<1>, and MODE to “0”, “1”, and “0”, respectively.

As a result, in a case where the default via dV can be used but the resistance value increases, the resistance value can be lowered by sharing the redundant via rV.

### 1.3.3 Third Modification of First Embodiment

In the first embodiment described above, the case where the signal SEL read from the fuse circuit 17 in the IF chip 10 is directly input to the TSV switching circuits 30-1 and 30-2 has been described, but the present embodiment is not limited thereto. For example, the signal SEL read from the fuse circuit 17 may be stored in a register provided in each chip. Hereinafter, a configuration different from that of the first embodiment will be mainly described. Description of configurations equivalent to those of the first embodiment will be omitted as appropriate.

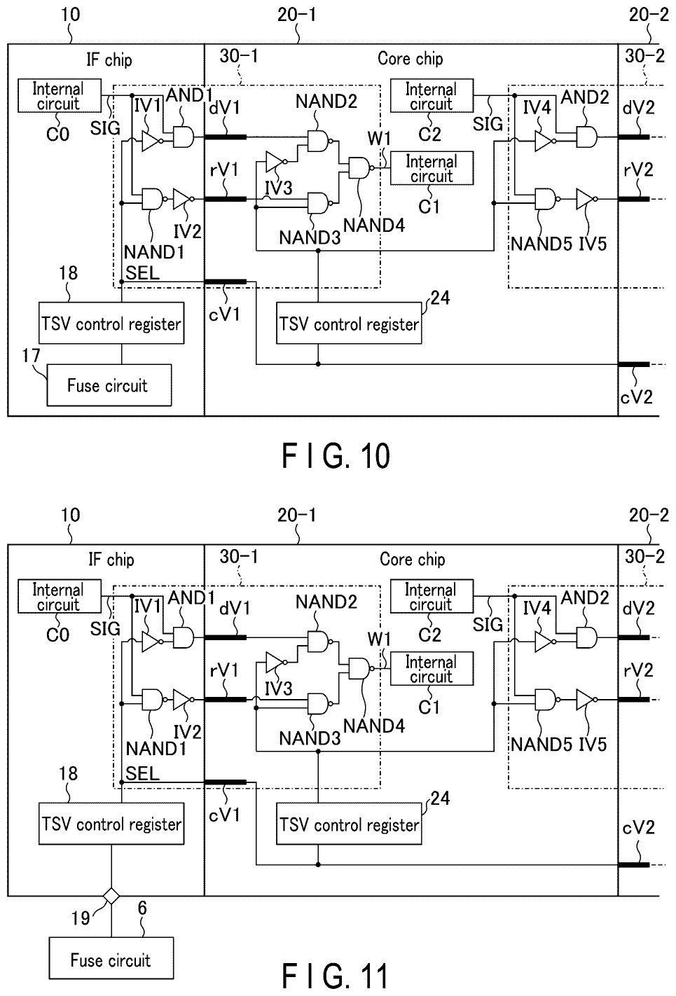

FIG. 10 is a circuit diagram showing an implementation example of a TSV switching circuit included in a memory device according to a third modification of the first embodiment. The configuration shown in FIG. 10 corresponds to the configuration in the first embodiment shown in FIG. 4.

As shown in FIG. 10, the IF chip 10 further includes a TSV control register 18. The core chip 20-1 further includes a TSV control register 24. Although not shown in FIG. 10, the core chips 20-2, 20-3, and 20-4 also have the same configuration as the core chip 20-1.

The TSV control register 18 stores, for example, information of the signal SEL stored in the fuse circuit 17 at the time of boot-up of the memory device 5. For example, the TSV control register 24 receives and stores information of the signal SEL stored in the TSV control register 18 through the control via cV1.

With the above configuration, it is possible to omit transmission of the signal SEL from the IF chip 10 to the core chip 20-1 at the time of transmission of the signal SIG. Furthermore, the information stored in the TSV control register 18 can be transferred to the TSV control register 24 using one control via cV1 regardless of the number of signals SEL. For example, in a case where the memory device 5 is boot-up, the sequencer 15 of the IF chip 10 writes the information stored in the fuse circuit 17 to the TSV control register 18. In addition, the sequencer 15 writes the information to the TSV control register 24 by serially transferring the information to each core chip 20 using the control via cV1. Note that the sequencer 15 may write different information for each core chip 20 in the TSV control register 24. As a result, different settings can be used for each core chip 20.

With such a configuration, the number of TSVs can be small as compared with the case of using the control vias cV1 according to the number of signals SEL.

### 1.3.4 Fourth Modification of First Embodiment

In the third modification of the first embodiment described above, the case where the information related to the signal SEL is stored in the fuse circuit 17 in the IF chip 10 has been described, but the present embodiment is not limited thereto. For example, the fuse circuit may be provided outside the IF chip 10. Hereinafter, a configuration different from that of the third modification of the first embodiment will be mainly described. Description of configurations equivalent to those of the third modification of the first embodiment will be omitted as appropriate.

FIG. 11 is a circuit diagram showing an implementation example of a TSV switching circuit included in a memory device according to a fourth modification of the first embodiment. The configuration shown in FIG. 11 corresponds to the configuration in the third modification of the first embodiment shown in FIG. 10.

As shown in FIG. 11, the fuse circuit 6 is provided outside the IF chip 10. Similarly to the third modification described with reference to FIG. 10, for example, the sequencer 15 writes the information of the signal SEL stored in the fuse circuit 6 into the TSV control register of each of the IF chip 10 and the core chip 20 through the pad 19 which is an input terminal of the IF chip 10 at the time of boot-up of the memory device 5.

With the above configuration, similarly to the third modification of the first embodiment, the number of TSVs can be small as compared with the case of using the control vias cV1 according to the number of signals SEL. In addition, since the IF chip 10 does not have to include a region for implementing the fuse circuit, a restriction on the layout of the IF chip 10 can be eased.

### 2. Second Embodiment

A memory device according to a second embodiment will be described. The second embodiment has a configuration for executing a test process for testing whether a TSV functions correctly. In the following description, configurations and operations different from those of the first embodiment will be mainly described. Description of configurations and operations equivalent to those of the first embodiment will be omitted as appropriate.

### 2.1 Functional Configuration Related to Test Process in Memory Device

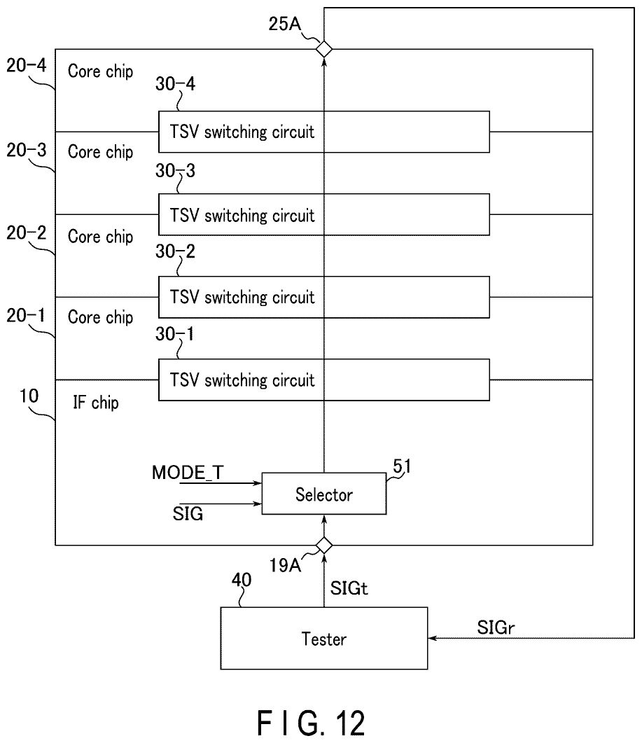

FIG. 12 is a block diagram showing an example of a functional configuration related to a test process in a memory device according to the second embodiment. As shown in FIG. 12, the IF chip 10 further includes a pad 19A and a selector 51. The core chip 20-4 further includes a pad 25A.

The pad 19A is a terminal for connecting, at the time of the test process, with a tester 40 which is a device external to the memory device 5. The IF chip 10 receives a test signal SIGt from the tester 40 through the pad 19A during the test process. The test signal SIGt is, for example, a data pattern in which 1-bit data is arranged in time series.

The test signal SIGt is input to the selector 51. Furthermore, a signal SIG is input to the selector 51. The selector 51 selects one of the signal SIG and the test signal SIGt as a signal transmitted from the IF chip 10 to the core chip 20-1 through a via V based on a signal MODE_T which is a 1-bit control signal. The signal MODE_T may be an internal signal controlled by a command from the host bus HB or a control signal from a tester input from a pad provided separately from the test signal SIGt. For example, in a case where the signal MODE_T is “1”, the selector 51 selects the test signal SIGt. In a case where the signal MODE_T is “0”, the selector 51 selects the signal SIG. The same applies to modifications of the second embodiment, a third embodiment, and a fourth embodiment, and modifications thereof.

In a case where the memory device 5 operates in a normal mode in which a normal process such as a write process and a read process is performed, the signal SIG is selected. On the other hand, in a case where the memory device 5 operates in a test mode in which a test process is performed, the test signal SIGt is selected. The test signal SIGt output from the selector 51 passes through the TSV switching circuits 30-1, 30-2, 30-3, and 30-4 and the pad 25A which is an external output terminal of the core chip 20-4, and then is input to the tester 40 as a return signal SIGr.

The tester 40 checks consistency between the test signal SIGt and the return signal SIGr. In a case where the test signal SIGt and the return signal SIGr match, the set of TSVs selected by the TSV switching circuits 30-1, 30-2, 30-3, and 30-4 is determined to be functioning correctly. On the other hand, in a case where the test signal SIGt and the return signal SIGr do not match, the set of TSVs selected by the TSV switching circuits 30-1, 30-2, 30-3, and 30-4 is determined to be functioning incorrectly. As described above, by performing the test process, the memory device 5 can determine the necessity of switching one or more TSVs in the TSV switching circuits 30-1, 30-2, 30-3, and 30-4.

### 2.2 Test Process

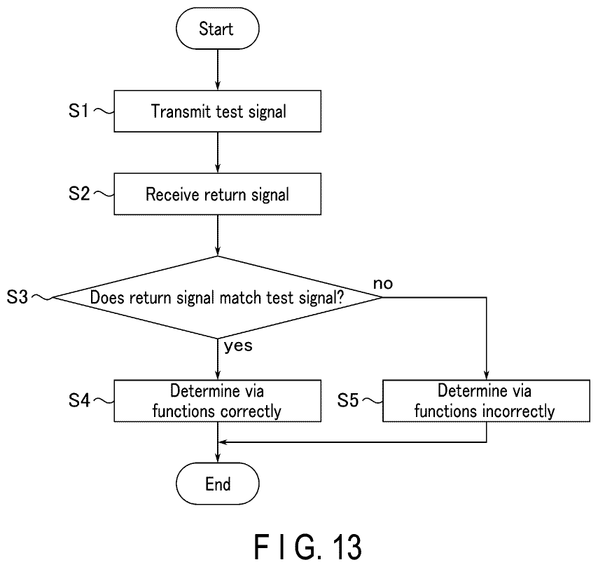

FIG. 13 is a flowchart showing an example of the test process in the memory device according to the second embodiment.

As shown in FIG. 13, in a case where the signal MODE_T is set to “1” and the memory device 5 is in the test mode (Start), the tester 40 transmits a test signal SIGt to the IF chip 10 (S1).

The IF chip 10 transmits the test signal SIGt to the core chip 20-4 through a set of TSVs set by the TSV switching circuits 30-1, 30-2, 30-3, and 30-4. The core chip 20-4 transmits the received test signal SIGt to the tester 40 as a return signal SIGr. With this configuration, the tester 40 receives the return signal SIGr (S2).

In step S3, the tester 40 determines whether or not the return signal SIGr received in the processing of step S2 matches the test signal SIGt transmitted in the processing of step S1.

In a case where the return signal SIGr matches the test signal SIGt (S3; yes), the tester 40 determines that the set of TSVs used at the time of transmitting the test signal SIGt functions correctly (S4).

In a case where the return signal SIGr does not match the test signal SIGt (S3; no), the tester 40 determines that the set of TSVs used at the time of transmitting the test signal SIGt functions incorrectly (S5).

After the processing of step S4 or after the processing of step S5, the test process ends (End).

As described above, in a case where it is determined in the processing of step S5 that there is an abnormality in the TSVs, a switch process of the TSVs may be performed after the test process. Specifically, for example, in response to the determination that the default via dV<0> and the default via dV<1> function correctly, the TSV switching circuit 30-1 is set such that the first state is selected. In response to the determination that the default via dV<0> functions incorrectly and the default via dV<1> functions correctly, the TSV switching circuit 30-1 is set such that the second state or the fourth state is selected. In response to the determination that the default via dV<0> functions correctly and the default via dV<1> functions incorrectly, the TSV switching circuit 30-1 is set such that the third state or the fifth state is selected.

### 2.3 Effects According to Second Embodiment

According to the second embodiment, the tester 40 transmits the test signal SIGt from the IF chip 10 to the core chip 20-4 through the vias in the test process. The tester 40 determines whether the vias function correctly or not based on the test signal SIGt having passed through the vias. As a result, information for switching a default via dV determined to be functioning incorrectly to a redundant via rV determined to be functioning correctly can be stored in the fuse circuit 17 before shipment. Therefore, even in a case where some of the default vias dV function incorrectly, the memory device 5 can be shipped.

### 2.4 Modification of Second Embodiment

In the second embodiment described above, the case where the test process using a set of the test signal SIGt and the return signal SIGr is performed for one signal SIG has been described, but the present embodiment is not limited thereto. For example, a test process using a set of the test signal SIGt and the return signal SIGr may be performed for a plurality of signals SIG. Hereinafter, configurations and operations different from those of the second embodiment will be mainly described. Description of configurations and operations equivalent to those of the second embodiment will be omitted as appropriate.

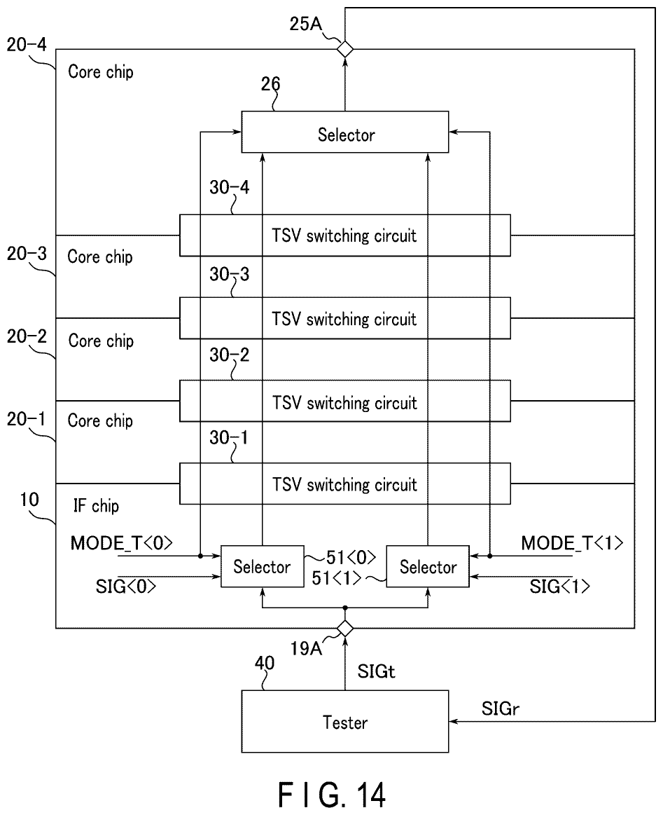

FIG. 14 is a block diagram showing an example of a functional configuration related to a test process in a memory device according to a modification of the second embodiment. The configuration shown in FIG. 14 corresponds to the configuration in the second embodiment shown in FIG. 12. As shown in FIG. 14, the IF chip 10 includes selectors 51<0> and 51<1> instead of the selector 51. The core chip 20-4 further includes a selector 26.

A test signal SIGt is input to the selector 51<0>. Furthermore, a signal SIG<0> is input to the selector 51<0>. The selector 51<0> selects one of the signal SIG<0> and the test signal SIGt as a signal transmitted from the IF chip 10 to the core chip 20-1 through a via V based on a signal MODE_T<0> which is a 1-bit control signal. For example, in a case where the signal MODE_T<0> is “1”, the selector 51<0> selects the test signal SIGt. In a case where the signal MODE_T<0> is “0”, the selector 51<0> selects the signal SIG<0>.

A test signal SIGt is also input to the selector 51<1>. Furthermore, a signal SIG<1> is input to the selector 51<1>. The selector 51<1> selects one of the signal SIG<1> and the test signal SIGt as a signal transmitted from the IF chip 10 to the core chip 20-1 through a via V based on a signal MODE_T<1> which is a 1-bit control signal. For example, in a case where the signal MODE_T<1> is “1”, the selector 51<1> selects the test signal SIGt. In a case where the signal MODE_T<1> is “0”, the selector 51<1> selects the signal SIG<1>.

In a case where the memory device 5 operates in a normal mode in which normal process such as a write process and a read process is performed, the signals SIG<0> and SIG<1> are selected. On the other hand, in a case where the memory device 5 operates in a test mode in which a test process is performed, the test signal SIGt is selected. The test signal SIGt output from each of the selectors 51<0> and 51<1> is input to the selector 26 in the core chip 20-4 after passing through the TSV switching circuits 30-1, 30-2, 30-3, and 30-4.

The selector 26 selects a signal to be input to the pad 25A based on the signals MODE_T<0> and MODE_T<1>. For example, in a case where the signal MODE_T<0> is “1” and the signal MODE_T<1> is “0”, the selector 26 selects the test signal SIGt input from the selector 51<0>. In a case where the signal MODE_T<0> is “0” and the signal MODE_T<1> is “1”, the selector 26 selects the test signal SIGt input from the selector 51<1>. The test signal SIGt output from the selector 26 is input to the tester 40 as a return signal SIGr through the pad 25A.

According to the modification of the second embodiment, the memory device 5 uses an interface with the tester 40 for transmitting the test signal SIGt commonly for a plurality of vias. With this configuration, since the number of the pads 19A and 25A can be reduced, the test process can be executed on a larger number of vias even in a case where the mounting area of the pads 19A and 25A cannot be secured.

### 3. Third Embodiment

Next, a memory device according to a third embodiment will be described. In the third embodiment, a test process can be performed in units of a plurality of sets of TSVs.

### 3.1 Functional Configuration Related to Test Process in Memory Device

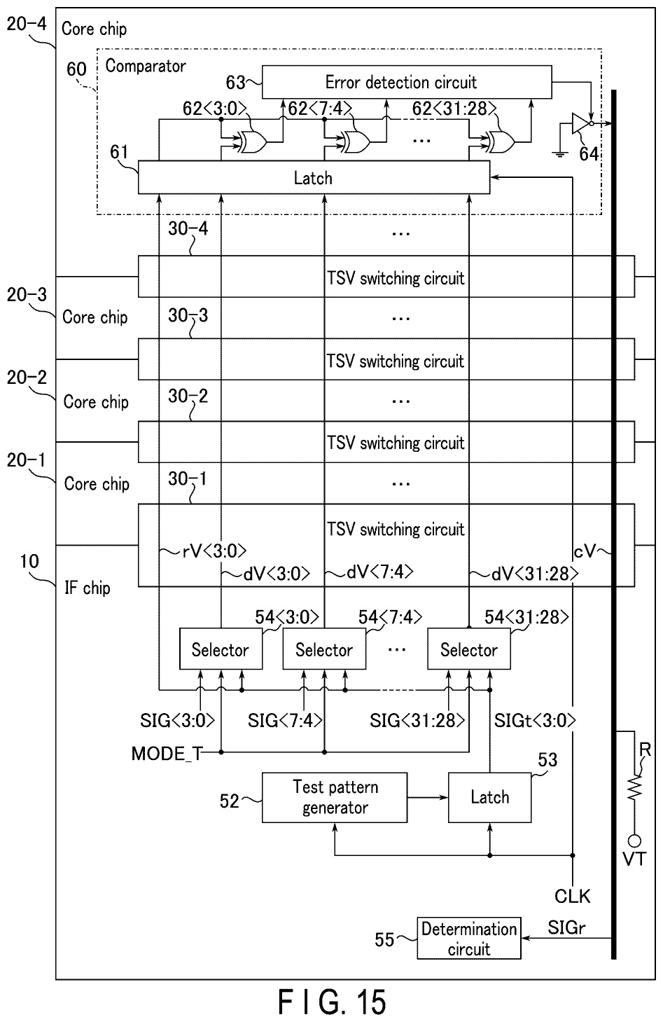

FIG. 15 is a block diagram showing an example of a functional configuration related to a test process in a memory device according to the third embodiment. As shown in FIG. 15, the IF chip 10 includes a test pattern generator 52, a latch 53, 32 selectors 54<31:0>, and a determination circuit 55. The core chip 20-4 includes a comparator 60.

Note that the TSV switching circuits 30-1, 30-2, 30-3, and 30-4 of the present embodiment shown in FIG. 15 are configured to be able to switch 32 default vias dV<31:0> and four redundant vias rV<3:0>, for example, by the same configuration as the first modification and the second modification of the first embodiment shown in FIGS. 6 to 9.

The test pattern generator 52 generates a test pattern as test signals SIGt<3:0> synchronized with a clock signal CLK. The test pattern is, for example, a data string of several bits. Specifically, the test pattern generator 52 can generate four types of test patterns “0000”, “1111”, “0101”, and “1010” as the test signals SIGt<3:0>, respectively.

The latch 53 transmits the test signals SIGt<3:0> received from the test pattern generator 52 to four interconnects respectively, in synchronization with the clock signal CLK.

The 32 selectors 54<31:0> are grouped into four selectors 54<3:0>, four selectors 54<7:4>, . . . , and four selectors 54<31:28>. The test signals SIGt<3:0> are input to the redundant vias rV<3:0> and the four selectors 54<4k+3:4k> (0≤k≤7). Furthermore, signals SIG<4k+3:4k> are input respectively to the four selectors 54<4k+3:4k>. Each of the four selectors 54<4k+3:4k> selects one of the signals SIG<4k+3:4k> and one of the test signals SIGt<3:0> as a signal transmitted from the IF chip 10 to the core chip 20-1 through the corresponding one of the default vias dV<4k+3:4k> based on a signal MODE_T.

For example, in a case where the signal MODE_T is “1”, the selectors 54<4k+3:4k> select the test signals SIGt<3:0>. In a case where the signal MODE_T is “0”, the selectors 54<4k+3:4k> select the signals SIG<4k+3:4k>.

With the above configuration, in a case of operating in the test mode, the test signal SIGt<0> is input to the redundant via rV<0> and the default vias dV<0>, dV<4>, . . . , and dV<28>. The test signal SIGt<1> is input to the redundant via rV<1> and the default vias dV<1>, dV<5>, . . . , and dV<29>. The test signal SIGt<2> is input to the redundant via rV<2> and the default vias dV<2>, dV<6>, . . . , and dV<30>. The test signal SIGt<3> is input to the redundant via rV<3> and the default vias dV<3>, dV<7>, . . . , and dV<31>. The test signals SIGt<3:0> having passed through the redundant vias rV<3:0> and each of the default vias dV<31:0> are input to the comparator 60 in the core chip 20-4.

The comparator 60 includes a latch 61, 32 exclusive OR circuits 62<31:0>, an error detection circuit 63, and a tri-state buffer 64.

The test signals SIGt<3:0> that have passed through the redundant vias rV<3:0> and each of the default vias dV<31:0> are input to the latch 61. The latch 61 captures the input test signals SIGt<3:0> in synchronization with the clock signal CLK.

Each of the exclusive OR circuits 62<4k+3:4k> has a first input terminal to which the corresponding one of the test signals SIGt<3:0> having passed through the corresponding one of the redundant vias rV<3:0> and captured into the latch 61 is input, a second input terminal to which the corresponding one of the test signals SIGt<3:0> having passed through the corresponding one of the default vias dV<4k+3:4k> and captured into the latch 61 are input, and an output terminal that outputs an exclusive OR operation result of the input signals.

The error detection circuit 63 determines matching between the test signals SIGt<3:0> passed through the redundant vias rV<3:0> and the test signals SIGt<3:0> passed through the default vias dV<4k+3:4k> based on the outputs from the exclusive OR circuits 62<4k+3:4k>. Specifically, for example, in a case where the outputs from the exclusive OR circuits 62<4k+3:4k> are “0” in all cycles, the error detection circuit 63 outputs a signal “0” to a control terminal of the tri-state buffer 64 as a 1-bit determination result indicating correctness (which means the test passed). In a case where at least one “1” is included in the outputs from the exclusive OR circuits 62<4k+3:4k>, the error detection circuit 63 outputs a signal of “1” to the control terminal of the tri-state buffer 64 as a 1-bit determination result indicating incorrectness (which means the test failed).

The tri-state buffer 64 has a grounded input terminal, the control terminal to which the output signal from the error detection circuit 63 is input, and an output terminal connected to the control via cV. In a case where “0” is output from the error detection circuit 63, the output of the tri-state buffer 64 is at a low (strong low) level. On the other hand, in a case where “1” is output from the error detection circuit 63, the output of the tri-state buffer 64 is high impedance (Hi-Z).

Note that, in the example of FIG. 15, the case where one tri-state buffer 64 is connected to the error detection circuit 63 has been described, but the present embodiment is not limited thereto. For example, eight OR circuits to which the outputs from the exclusive OR circuits 62<4k+3:4k> are input may be provided. In this case, by providing eight tri-state buffers to which the outputs from the eight OR circuits are input, respectively, the same function as the configuration of FIG. 15 can be provided.

The control via cV is connected to a power supply VT through a resistor R in the IF chip 10. The power supply VT weakly drives the control via cV to a high (weak high) level. Therefore, in a case where the output of the tri-state buffer 64 is at the low level, the control via cV is driven to the low level. On the other hand, in a case where the output of the tri-state buffer 64 is high impedance, the control via cV is not at the low level (that is, at the high level).

The determination circuit 55 is connected to the control via cV in the IF chip 10. The determination circuit 55 receives a voltage level of the control via cV as a return signal SIGr to determine the result of the test process. Specifically, in a case where the return signal SIGr is at the low level for all the cycles of the test process, the determination circuit 55 determines that all vias that are targets of the test process function correctly. In a case where the return signal SIGr is at the high level for all the cycles of the test process, the determination circuit 55 determines that the redundant vias rV<3:0> function incorrectly. In a case where both the low-level return signal SIGr and the high-level return signal SIGr are included, the determination circuit 55 determines that the default vias dV<4k+3:4k> corresponding to the high-level return signal SIGr function incorrectly.

With the above configuration, the TSV switching circuits 30-1, 30-2, 30-3, and 30-4 can switch the default vias dV<4k+3:4k> determined to be functioning incorrectly to the redundant vias rV<3:0> functioning correctly, based on the determination result by the determination circuit 55.

### 3.2 Test Process

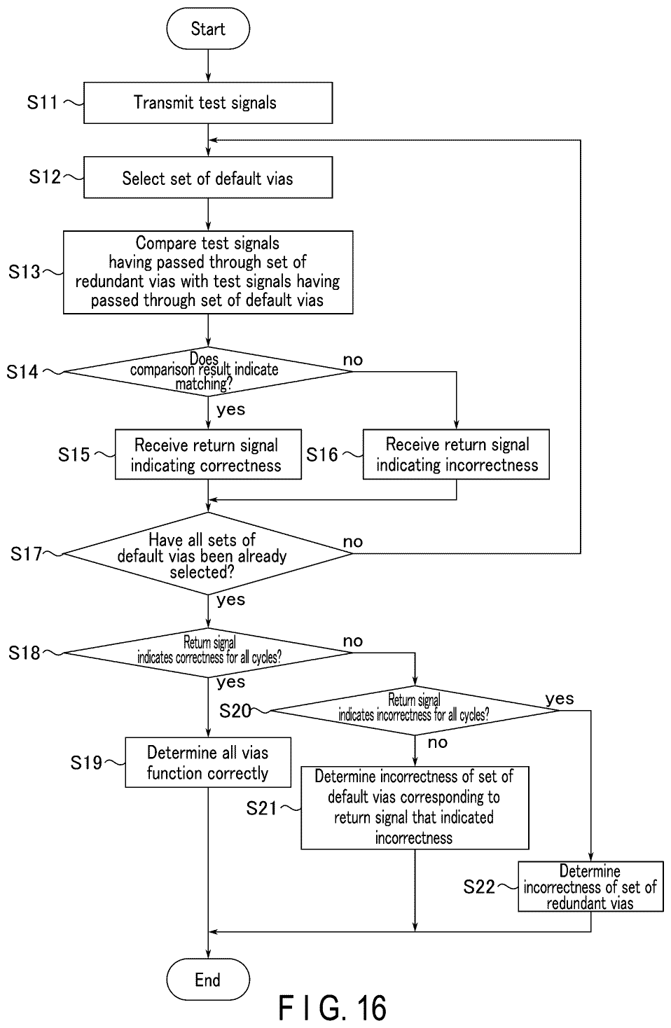

FIG. 16 is a flowchart showing an example of the test process in the memory device according to the third embodiment.

As shown in FIG. 16, in a case where the signal MODE_T is set to “1” and the memory device 5 enters the test mode (Start), the test pattern generator 52 and the latch 53 transmit test signals SIGt<3:0> in accordance with the clock signal CLK (S11).

The test signal SIGt<0> is stored in the latch 61 through the redundant via rV<0> and each of the default vias dV<0>, dV<4>, . . . , and dV<28>. The test signal SIGt<1> is stored in the latch 61 through the redundant via rV<1> and each of the default vias dV<1>, dV<5>, . . . , and dV<29>. The test signal SIGt<2> is stored in the latch 61 through the redundant via rV<2> and each of the default vias dV<2>, dV<6>, . . . , and dV<30>. The test signal SIGt<3> is stored in the latch 61 through the redundant via rV<3> and each of the default vias dV<3>, dV<7>, . . . , and dV<31>.

The comparator 60 selects four default vias dV<4k+3:4k> corresponding to an unselected variable k (0≤k≤7) as a set of default vias (S12).

In step 513, the exclusive OR circuits 62<4k+3:4k> compare the test signals SIGt<3:0> having passed through the redundant vias rV<3:0>, with the test signals SIGt<3:0> having passed through the default vias dV<4k+3:4k> selected in the processing of step S12.

The error detection circuit 63 determines whether the test signals SIGt<3:0> compared in the processing of step S13 match each other (S14).

In a case where the comparison result indicates matching (S14; yes), the determination circuit 55 receives the return signal SIGr indicating correctness(S15). Specifically, the error detection circuit 63 outputs a signal “0” indicating correctness. As a result, the tri-state buffer 64 drives the control via cV to the low level. Therefore, the determination circuit 55 receives the low-level return signal SIGr indicating correctness.

In a case where the comparison result does not indicate matching (S14; no), the determination circuit 55 receives the return signal SIGr indicating incorrectness (S16). Specifically, the error detection circuit 63 outputs a signal “1” indicating incorrectness. As a result, the tri-state buffer 64 has high impedance. This results in that the control via cV is driven to the high level. Therefore, the determination circuit 55 receives a high-level return signal SIGr indicating incorrectness.

The memory device 5 determines whether all sets of default vias have been selected (S17).

In a case where there is a set of unselected default vias (S17; no), the comparator 60 selects four default vias dV<4k+3:4k> corresponding to the unselected variable k as a set of default vias (S12). Then, the processing of subsequent steps S13 to S17 is executed. In this manner, the processing of steps S12 to S17 is executed until all the sets of default vias are selected.

In a case where all the sets of default vias have been selected (S17; yes), the determination circuit 55 determines whether or not the return signal SIGr indicates correctness for all the cycles of the test process (S18).

In a case where the return signal SIGr indicates correctness for all the cycles of the test process (S18; yes), the determination circuit 55 determines that all vias (that is, the redundant vias rV<3:0> and the default vias dV<31:0>) that are targets of the test process are functioning correctly (S19).

In a case where there is the return signal SIGr indicating incorrectness (S18; no), the determination circuit 55 determines whether or not the return signal SIGr indicates incorrectness for all the cycles of the test process (S20).

In a case where both the return signal SIGr indicating correctness and the return signal SIGr indicating incorrectness are included (S20; no), the determination circuit 55 determines that the default vias dV<4k+3:4k> corresponding to the return signal SIGr indicating the incorrectness function incorrectly (S21).

In a case where all the return signal SIGr indicates incorrectness for all the cycles of the test process (S20; yes), the determination circuit 55 determines that the redundant vias rV<3:0> function incorrectly (S22).

After the processing of step S19, the processing of step S21, or the processing of step S22, the test process ends (End).

In a case where it is determined in the processing of step S16 that there is an incorrectness in the TSV, the switch process of the TSVs may be performed after the test process. Specifically, for example, in response to the determination that a default via dV<0> and a default via dV<1> function correctly, the TSV switching circuit 30-1 is set such that the first state is selected. In response to the determination that the default via dV<0> functions incorrectly and the default via dV<1> functions correctly, the TSV switching circuit 30-1 is set such that the second state or the fourth state is selected. In response to the determination that the default via dV<0> functions correctly and the default via dV<1> functions incorrectly, the TSV switching circuit 30-1 is set such that the third state or the fifth state is selected.

### 3.3 Effects According to Third Embodiment

According to the third embodiment, the error detection circuit 63 executes a first process to an eighth process of determining consistency between the test signals SIGt<3:0> having passed through the redundant vias rV<3:0> and the test signals SIGt<3:0> having passed through each of the default vias dV<4k+3:4k>(0≤k≤7). In a case where the results of the first process to the eighth process all indicate matching, the determination circuit 55 determines that the redundant vias <3:0> and the default vias dV<31:0> are all functioning correctly. In a case where all the results of the first process to the eighth process indicate mismatching, the determination circuit 55 determines that the redundant vias <3:0> are functioning incorrectly and the default vias dV<31:0> are functioning correctly. In a case where, for example, the result of the first process indicates mismatching, the determination circuit 55 determines that the default vias dV<3:0> corresponding to the first process indicating mismatching are functioning incorrectly, and the redundant vias rV<3:0> and the default vias dV<31:4> are functioning correctly. Furthermore, in a case where the result of the second process indicates mismatching, the determination circuit 55 determines that the default vias dV<7:4> corresponding to the second process indicating mismatching are functioning incorrectly, and the redundant vias rV<3:0> and the default vias dV<31:8> and dV<3:0> are functioning correctly. As a result, under the circumstance where the failure rate of TSV is regarded as very low, the test process can be easily performed.

In addition, the above-described consistency determination process is performed in synchronization with the clock signal CLK. As a result, a case where a signal cannot be transmitted in a period shorter than the clock signal CLK, due to an increase in the resistance value of the via, can be determined as incorrectness. Therefore, not only an open defect but also a resistance value defect can be detected by the test process.

### 4. Fourth Embodiment

Next, a memory device according to a fourth embodiment will be described. In the fourth embodiment, a test process is sequentially performed on all vias with a 1-bit test pattern.

### 4.1 Functional Configuration Related to Test Process in Memory Device

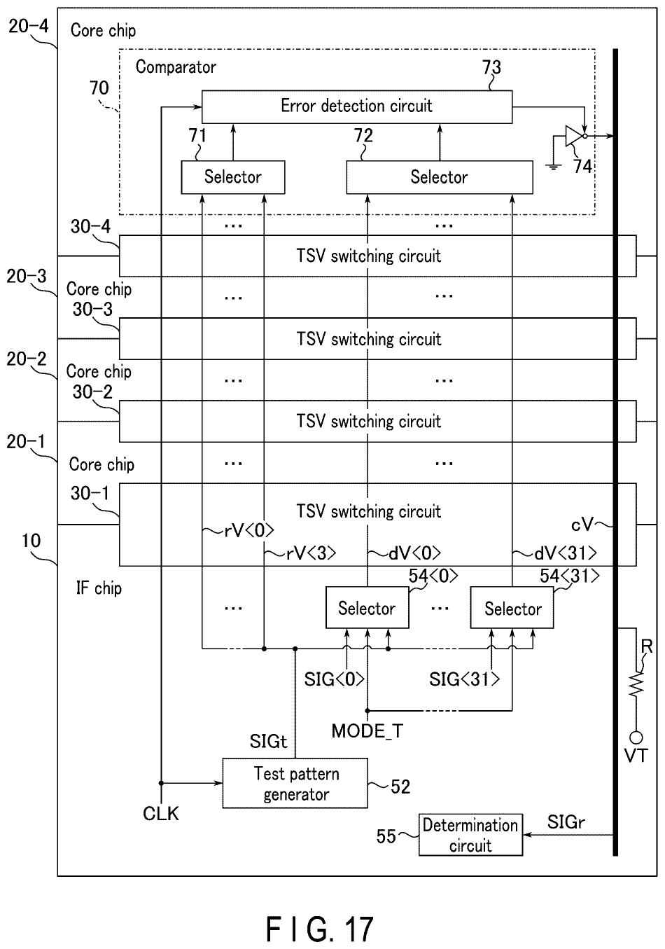

FIG. 17 is a block diagram showing an example of a functional configuration related to a test process in the memory device according to the fourth embodiment. As shown in FIG. 17, the IF chip 10 includes the test pattern generator 52, the 32 selectors 54<31:0>, and the determination circuit 55. The core chip 20-4 includes a comparator 70.

The test pattern generator 52 generates a 1-bit test signal SIGt. Such a test signal SIGt is used to confirm the conduction of vias. The test signal SIGt is, for example, “1”. The test pattern generator 52 outputs the generated test signal SIGt in synchronization with the clock signal CLK.

The test signal SIGt is input to the redundant vias rV<3:0> and the 32 selectors 54<31:0>. Furthermore, signals SIG<31:0> are input to the 32 selectors 54<31:0>. Each of the 32 selectors 54<31:0> selects one of the signal SIG<31:0> and the test signal SIGt as a signal transmitted from the IF chip 10 to the core chip 20-1 through the corresponding one of the default vias dV<31:0> based on a signal MODE_T.

For example, in a case where the signal MODE_T is “1”, each of the selectors 54<31:0> selects the test signal SIGt. In a case where the signal MODE_T is “0”, the selectors 54<31:0> select the signals SIG<31:0>. With the above configuration, in a case of operating in a test mode, the test signal SIGt is input to the redundant vias rV<3:0> and the default vias dV<31:0>. The test signals SIGt having passed through the redundant vias rV<3:0> and the default vias dV<31:0> are input to the comparator 70 in the core chip 20-4.

The comparator 70 includes selectors 71 and 72, an error detection circuit 73, and a tri-state buffer 74.

The selector 71 receives the four test signals SIGt that have passed through the redundant vias rV<3:0>. The selector 71 outputs one of the four test signals SIGt selected by the memory device 5.

The selector 72 receives the 32 test signals SIGt that have passed through the default vias dV<31:0>. The selector 72 outputs one of the 32 test signals SIGt selected by the memory device 5.

The error detection circuit 73 determines whether each of the redundant vias rV<3:0> functions correctly based on the clock signal CLK and the test signal SIGt output from the selector 71. Specifically, in a case where the test signal SIGt input from the selector 71 is “1”, the error detection circuit 73 outputs, as a determination result, a signal of “0” indicating that the corresponding redundant via rV functions correctly to a control terminal of the tri-state buffer 74. In a case where the test signal SIGt input from the selector 71 is “0”, the error detection circuit 73 outputs, as a determination result, a signal of “1” indicating that the corresponding redundant via rV functions incorrectly to the control terminal of the tri-state buffer 74.

In addition, the error detection circuit 73 determines whether each of the default vias dV<31:0> functions correctly based on the clock signal CLK and the test signal SIGt output from the selectors 71 and 72. Specifically, in a case where the test signal SIGt input from the selector 72 match the test signal SIGt input from the selector 71, the error detection circuit 73 outputs a signal “0” indicating that the corresponding default via dV functions correctly to the control terminal of the tri-state buffer 74 as a determination result. In a case where the test signal SIGt input from the selector 72 does not match the test signal SIGt input from the selector 71, the error detection circuit 73 outputs a signal “1” indicating that the corresponding default via dV functions incorrectly to the control terminal of the tri-state buffer 74 as a determination result. Note that the test signal SIGt that is determined to have correctly passed through the redundant via rV is used as the test signal SIGt output from the selector 71 at the time of the determination.

The tri-state buffer 74 has a grounded input terminal, the control terminal to which the output signal from the error detection circuit 73 is input, and an output terminal connected to the control via cV. In a case where “0” is output from the error detection circuit 73, the output of the tri-state buffer 74 is at a low level. On the other hand, in a case where “1” is output from the error detection circuit 73, the output of the tri-state buffer 74 is high impedance.

The control via cV is connected to a power supply VT through a resistor R in the IF chip 10. The power supply VT weakly drives the control via cV to the high level. Therefore, in a case where the output of the tri-state buffer 74 is at the low level, the control via cV is driven to the low level. On the other hand, in a case where the output of the tri-state buffer 74 is high impedance, the control via cV is not at the low level (that is, at the high level).

The determination circuit 55 is connected to the control via cV in the IF chip 10. The determination circuit 55 receives a voltage level of the control via cV as a return signal SIGr to determine the result of the test process. Specifically, in the conduction confirmation of the redundant via rV (a test process for the redundant via rV), the determination circuit 55 determines that the corresponding redundant via rV functions correctly in a case where the return signal SIGr is at the low level, and determines that the corresponding redundant via rV functions incorrectly in a case where the return signal SIGr is at the high level. In the consistency confirmation between the redundant via rV and the default via dV (a test process for the default via dV), the determination circuit 55 determines that the corresponding default via dV functions correctly in a case where the return signal SIGr is at the low level, and determines that the corresponding default via dV functions incorrectly in a case where the return signal SIGr is at the high level.

With the above configuration, the TSV switching circuits 30-1, 30-2, 30-3, and 30-4 can switch the default via dV determined to be functioning incorrectly to the redundant via rV functioning correctly based on the determination result by the determination circuit 55.

### 4.2 Test Process

### 4.2.1 Test Process for Redundant Vias

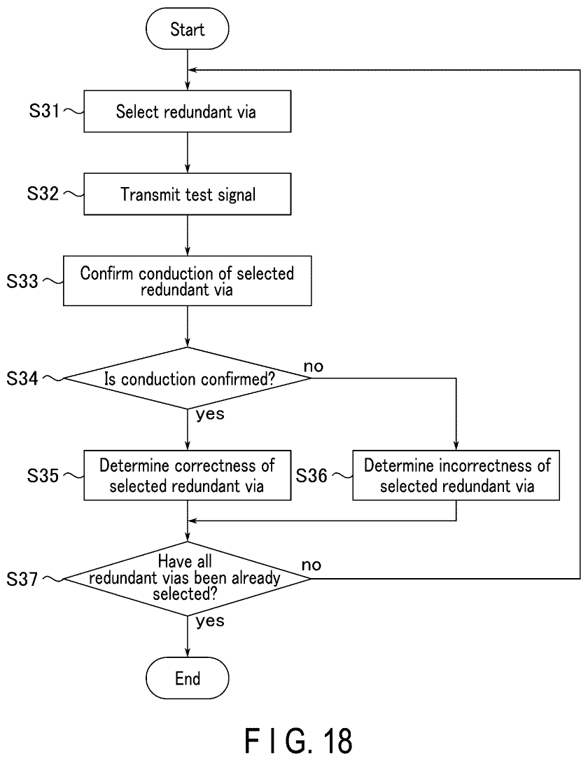

FIG. 18 is a flowchart showing an example of the test process for the redundant vias in the memory device according to the fourth embodiment.

As shown in FIG. 18, in a case where the signal MODE_T is set to “1” and the memory device 5 enters the test mode (Start), the selector 71 selects one of the redundant vias rV<3:0> (S31). In this case, the selector 72 does not select any of the default vias dV<31:0>.

The test pattern generator 52 transmits the test signal SIGt in accordance with the clock signal CLK (S32). The selector 71 transmits the test signal SIGt that has passed through the redundant via rV selected in the processing of step S31 to the error detection circuit 73.

Based on the clock signal CLK and the test signal SIGt received from the selector 71, in step S33, the error detection circuit 73 confirms conduction of the redundant via rV selected in the processing of step S31.

The error detection circuit 73 determines whether the conduction of the selected via is confirmed (S34).

In a case where the conduction is confirmed (S34; yes), the determination circuit 55 determines that the redundant via rV selected in the processing of step S31 functions correctly (S35). Specifically, the error detection circuit 73 outputs a signal “0” indicating correctness. As a result, the tri-state buffer 74 drives the control via cV to the low level. The determination circuit 55 determines that the corresponding redundant via rV functions correctly by receiving the low-level return signal SIGr indicating correctness.

In a case where the conduction is not confirmed (S34; no), the determination circuit 55 determines that the redundant via rV selected in the process of step S31 functions incorrectly (S36). Specifically, the error detection circuit 73 outputs a signal “1” indicating incorrectness. As a result, the tri-state buffer 74 has high impedance. As a result, the control via cV is driven to the high level. The determination circuit 55 determines that the corresponding redundant via rV functions incorrectly by receiving the high-level return signal SIGr indicating incorrectness.

The memory device 5 determines whether all the redundant vias rV have been selected (S37).

In a case where there is an unselected redundant via rV (S37; no), the selector 71 selects the unselected redundant via rV (S31). Then, the processing of subsequent steps S32 to S37 is executed. In this manner, the processing of steps S31 to S37 is executed until all the redundant vias rV are selected.

In a case where all the redundant vias rV have been selected (S37; yes), the test process for the redundant vias rV ends (End).

### 4.2.2 Test Process for Default Vias

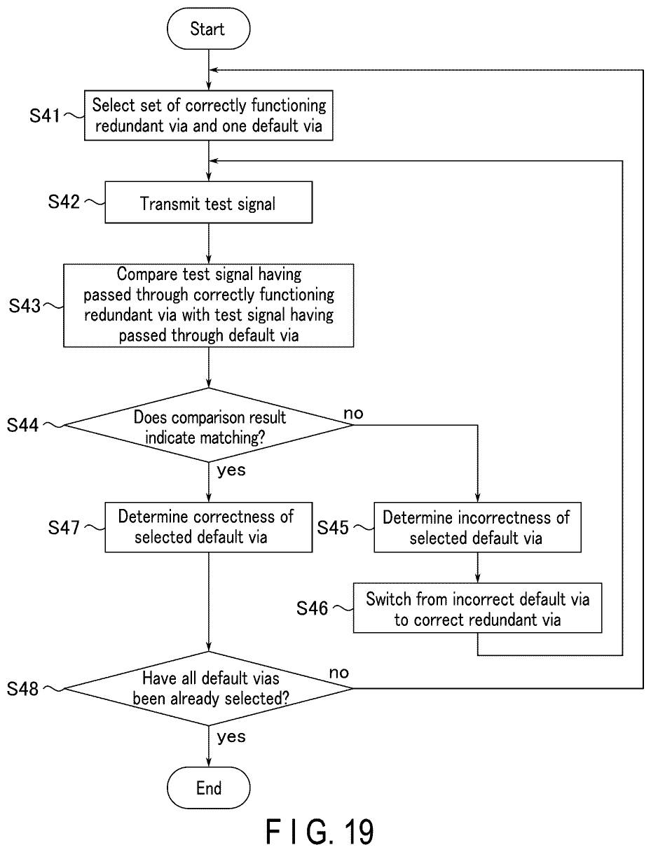

FIG. 19 is a flowchart showing an example of a test process for the default vias in the memory device according to the fourth embodiment.

As shown in FIG. 19, after the test process for the redundant vias rV (Start), the selectors 71 and 72 select a set of a correctly functioning redundant via rV and one of the default vias dV<31:0> (S41).

The test pattern generator 52 transmits the test signal SIGt in accordance with the clock signal CLK (S42). The selector 71 transmits the test signal SIGt that has passed through the correctly functioning redundant via rV selected in the process of step S41 to the error detection circuit 73. The selector 72 transmits the test signal SIGt that has passed through the default via dV selected in the processing of step S41 to the error detection circuit 73.

Based on the clock signal CLK and the test signal SIGt received from each of the selectors 71 and 72, in step S43, the error detection circuit 73 compares the test signals SIGt having passed through the redundant via rV and the default via dV selected in the processing of step S41.

The error detection circuit 73 determines whether or not the test signals SIGt compared in the processing of step S43 coincide with each other (S44).

In a case where the comparison result does not indicate matching (S44; no), the determination circuit 55 determines that the default via dV selected in the processing of step S41 functions incorrectly (S45). Specifically, the error detection circuit 73 outputs a signal “1” indicating incorrectness. As a result, the tri-state buffer 74 has high impedance. This results in that the control via cV is driven to the high level. The determination circuit 55 determines that the corresponding default via dV functions incorrectly by receiving the high-level return signal SIGr indicating incorrectness.

After the processing of step S45, the TSV switching circuits 30-1, 30-2, 30-3, and 30-4 perform switching from the default via dV determined to be incorrect in the processing of step S45 to the correctly functioning redundant via rV (S46).

Specifically, for example, in response to the determination that the default via dV<0> and the default via dV<1> function correctly, the TSV switching circuit 30-1 is set such that the first state is selected. In response to the determination that the default via dV<0> functions incorrectly and the default via dV<1> functions correctly, the TSV switching circuit 30-1 is set such that the second state or the fourth state is selected. In response to the determination that the default via dV<0> functions correctly and the default via dV<1> functions incorrectly, the TSV switching circuit 30-1 is set such that the third state or the fifth state is selected.

After the processing of step S46, the test pattern generator 52 transmits the test signal SIGt in accordance with the clock signal CLK (S42). Then, the processing of subsequent step S43 and the processing of step S44 are executed. In this manner, the processing of steps S42 to S46 is executed until the comparison results match.

In a case where the comparison result indicates matching (S44; yes), the determination circuit 55 determines that the default via dV selected in the processing of step S41 functions correctly (S47). Specifically, the error detection circuit 73 outputs a signal “0” indicating correctness. As a result, the tri-state buffer 74 drives the control via cV to the low level. The determination circuit 55 determines that the corresponding default via dV functions correctly by receiving the low-level return signal SIGr indicating correctness.

After the processing of step S47, the memory device 5 determines whether or not all the default vias dV have been selected (S48).

In a case where there is an unselected default via dV (S48; no), the selectors 71 and 72 select another set of a correctly functioning redundant vias rV and one of the unselected default vias dV (S41). Then, the processing of subsequent steps S42 to S48 is executed. In this manner, the processing of steps S41 to S48 is executed until all the default vias dV are selected.

In a case where all the default vias dV have been selected (S48; yes), the test process for the default vias dV ends (End).

### 4.3 Effects According to Fourth Embodiment

According to the fourth embodiment, the memory device 5 first determines the quality of each of the redundant vias rV<3:0>. Next, the memory device 5 determines consistency between the test signal SIGt having passed through the redundant via rV determined to be functioning correctly and the test signal SIGt having passed through the default via dV. As a result, it is possible to efficiently execute switching to the correctly functioning redundant via rV in a case where an incorrectness is found in the default via dV.

Further, the consistency determination process is performed by the 1-bit test signal SIGt. As a result, the test pattern generator 52 can be simplified.

### 4.4 Modification of Fourth Embodiment

In the above-described fourth embodiment, the case where the test signal SIGt is generated in the IF chip 10 and the determination based on the return signal SIGr is performed has been described, but the present embodiment is not limited thereto. For example, the generation of the test signal SIGt and the determination based on the return signal SIGr may be performed by the tester 40. Hereinafter, configurations and operations different from those of the fourth embodiment will be mainly described. Description of configurations and operations equivalent to those of the fourth embodiment will be omitted as appropriate.

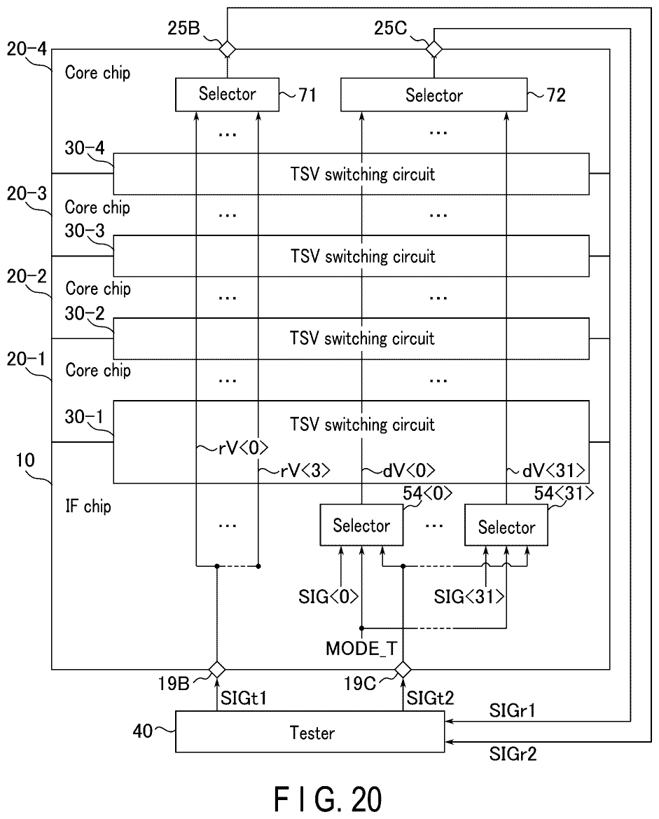

FIG. 20 is a block diagram showing an example of a functional configuration related to test process in a memory device according to a modification of the fourth embodiment. The configuration shown in FIG. 20 corresponds to the configuration in the fourth embodiment shown in FIG. 17. As shown in FIG. 20, the IF chip 10 includes pads 19B and 19C, and may not include the test pattern generator 52. The core chip 20-4 includes pads 25B and 25C, and may not include the error detection circuit 73 and the tri-state buffer 74.

The pads 19B and 19C are terminals for connecting the IF chip 10 and the tester 40. In the test process, the IF chip 10 receives test signals SIGt1 and SIGt2 from the tester 40 through the pads 19B and 19C, respectively. The test signal SIGt1 input through the pad 19B passes through the redundant vias rV<3:0> and is transmitted to the selector 71. The test signal SIGt2 input through the pad 19C is transmitted to the selector 72 through the default vias dV<31:0>. Each of the test signals SIGt1 and sIGt2 is, for example, a 1-bit signal.

The pads 25B and 25C are terminals for connecting the core chip 20-4 and the tester 40. The selector 71 transmits the test signal SIGt1 having passed through a selected redundant via rV to the tester 40 through the pad 25B. The selector 72 transmits the test signal SIGt2 having passed through a selected one of the default vias dV<31:0> to the tester 40 through the pad 25C.

The tester 40 receives the signals output from the pads 25B and 25C of the core chip 20-4 as return signals SIGr and SIGr2, respectively. The tester 40 performs the test process for the redundant via rV based on the test signal SIGt1 and the return signal SIGr1. The tester 40 performs the test process for the default via dV based on the test signals SIGt1 and SIGt2 and the return signals SIGr and SIGr2.

According to the modification of the fourth embodiment, the generation of the test signal SIGt and the correctness/incorrectness determination of the via are executed by the tester 40. As a result, the number of circuits mounted on the IF chip 10 and the core chip 20-4 can be reduced.

### 5. Fifth Embodiment

Next, a memory device according to a fifth embodiment will be described. In the fifth embodiment, a test process is collectively performed on all the vias to be subjected to the test process.

### 5.1 Functional Configuration Related to Test Process in Memory Device

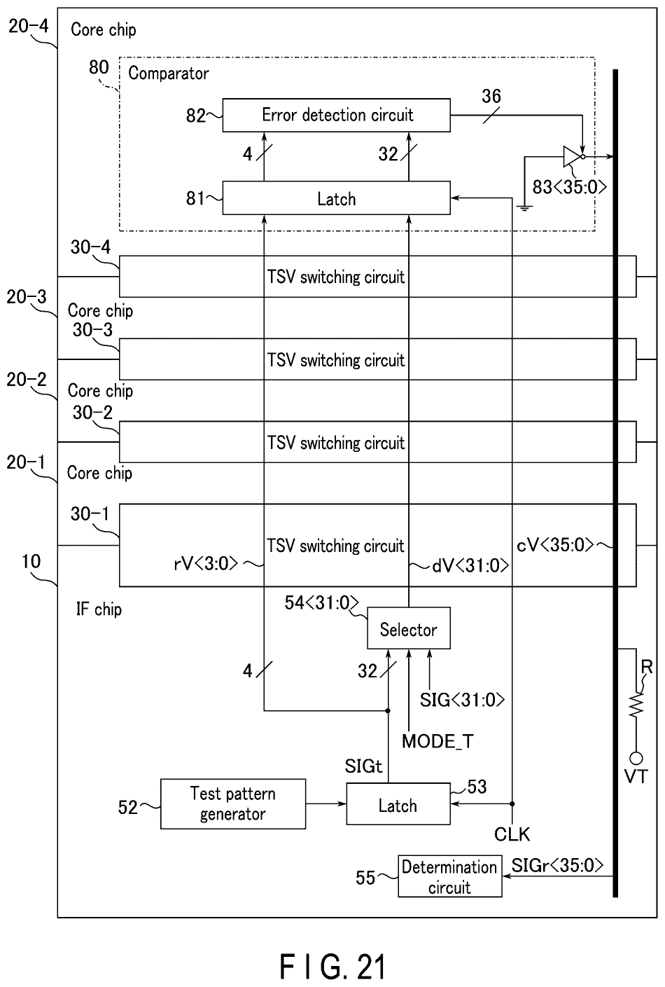

FIG. 21 is a block diagram showing an example of a functional configuration related to a test process in the memory device according to the fifth embodiment. As shown in FIG. 21, the IF chip 10 includes the test pattern generator 52, the latch 53, the 32 selectors 54<31:0>, and the determination circuit 55. The core chip 20-4 includes a comparator 80.

The test pattern generator 52 generates a 1-bit test signal SIGt. Such a test signal SIGt is used to confirm the conduction of vias. The test signal SIGt is, for example, “1”. The test pattern generator 52 transmits the generated test signal SIGt to the latch 53.

The latch 53 synchronizes the test signal SIGt with the clock signal CLK and transmits the test signals SIGt<35:0> to 36 interconnects.

The test signals SIGt<35:32> are input to the redundant vias rV<3:0>. The test signals SIGt<31:0> are input to the 32 selectors 54<31:0>. Furthermore, signals SIG<31:0> are input to the 32 selectors 54<31:0>. Each of the 32 selectors 54<31:0> selects one of the signals SIG<31:0> and one of the test signals SIGt<31:0> as a signal transmitted from the IF chip 10 to the core chip 20-1 through the default vias dV<31:0> based on a signal MODE_T.

For example, in a case where the signal MODE_T is “1”, each of the selectors 54<31:0> selects the corresponding one of the test signals SIGt<31:0>. In a case where the signal MODE_T is “0”, the selectors 54<31:0> select the signals SIG<31:0>. With the above configuration, in a case of operating in the test mode, the test signals SIGt<35:0> are input to the redundant vias rV<3:0> and the default vias dV<31:0>. The test signals SIGt<35:0> having passed through the redundant vias rV<3:0> and the default vias dV<31:0> are input to the comparator 80 in the core chip 20-4.

The comparator 80 includes a latch 81, an error detection circuit 82, and 36 tri-state buffers 83<35:0>.

The test signals SIGt<35:0> having passed through the redundant vias rV<3:0> and the default vias dV<31:0> are input to the latch 81. The latch 81 latches the input test signals SIGt<35:0> in synchronization with the clock signal CLK.

The error detection circuit 82 determines whether each of the redundant vias rV<3:0> and the default vias <31:0> functions correctly based on the test signals SIGt<35:0> input from the latch 81. Specifically, in a case where the test signal SIGt having passed through a certain redundant via rV or a certain default via dV is “1”, a signal “0” indicating that the redundant via rV or the default via dV functions correctly is output to a control terminal of the corresponding tri-state buffer 83 as a determination result. In a case where the test signal SIGt having passed through a certain redundant via rV or a certain default via dV is “0”, as a determination result, a signal “1” indicating that the redundant via rV or the default via dV functions incorrectly is output to the control terminal of the corresponding tri-state buffer 83.

Each of the tri-state buffers 83<35:0> has a grounded input terminal, the control terminal to which the output signal from the error detection circuit 82 is input, and an output terminal. The output terminals of the tri-state buffers 83<35:0> are connected to control vias cV<35:0>, respectively. In a case where a signal “0” is output from the error detection circuit 82 with respect to a default via dV<i>, the output of the tri-state buffer 83<i> is at a low level (0≤i≤31). In a case where a signal “0” is output from the error detection circuit 82 with respect to a redundant via rV<j>, the output of the tri-state buffer 83<32+j> becomes the low level (0≤j≤3). On the other hand, in a case where “1” is output from the error detection circuit 82 with respect to the default via dV<i>, the output of the tri-state buffer 83<i> is high impedance. In a case where “1” is output from the error detection circuit 82 with respect to the redundant via rV<j>, the output of the tri-state buffer 83<32+j> becomes high impedance.

Each of the control vias cV<35:0> is connected to a power supply VT through a resistor R in the IF chip 10. The power supply VT weakly drives each of the control vias cV<35:0> to a high level. Therefore, in a case where the output of a certain tri-state buffer 83 is at the low level, the corresponding control via cV is driven to the low level. On the other hand, in a case where the output of a certain tri-state buffer 83 is high impedance, the corresponding control via cV is not at the low level (that is, at the high level).

The determination circuit 55 is connected to each of the control vias cV<35:0> in the IF chip 10. The determination circuit 55 receives the voltage level of the control vias cV<35:0> as the return signals SIGr<35:0> to determine the result of the test process. Specifically, the determination circuit 55 determines that the corresponding default via dV<i> functions correctly in a case where the return signal SIGr<i> is at the low level, and determines that the corresponding default via dV<i> functions incorrectly in a case where the return signal SIGr<i> is at the high level. The determination circuit 55 determines that the corresponding redundant via rV<j> functions correctly in a case where the return signal SIGr<32+j> is at the low level, and determines that the corresponding redundant via rV<j> functions incorrectly in a case where the return signal SIGr<32+j> is at the high level.

With the above configuration, the TSV switching circuits 30-1, 30-2, 30-3, and 30-4 can switch the default via dV determined to be functioning incorrectly to a correctly functioning redundant via rV based on the determination result by the determination circuit 55.

### 5.2 Test Process

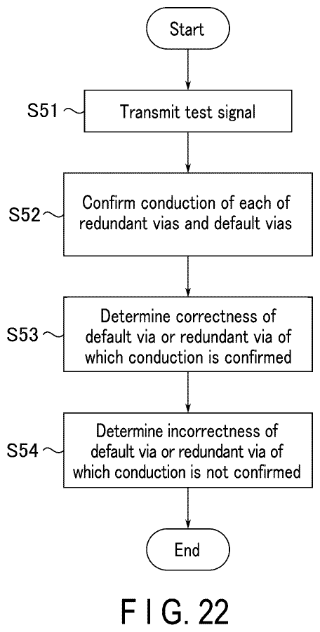

FIG. 22 is a flowchart showing an example of the test process in the memory device according to the fifth embodiment.

As shown in FIG. 22, in a case where the signal MODE_T is set to “1” and the memory device 5 enters the test mode (Start), the test pattern generator 52 transmits the test signal SIGt in accordance with the clock signal CLK (S51). The latch 81 transmits the test signals SIGt having passed through the redundant vias rV<3:0> and the default vias dV<31:0> to the error detection circuit 82 in synchronization with the clock signal CLK.

The error detection circuit 82 performs conduction confirmation of each of the redundant vias rV<3:0> and the default vias dV<31:0> (S52).

The determination circuit 55 determines that the redundant via rV or the default via dV of which conduction is confirmed in step S52 functions correctly (S53).

Specifically, in a case where the conduction of the default via dV<i> is confirmed, the error detection circuit 82 outputs a signal “0” indicating correctness to the tri-state buffer 83<i>. As a result, the tri-state buffer 83<i> drives the corresponding control via cV<i> to the low level. The determination circuit 55 determines that the corresponding default via dV<i> functions correctly by receiving the low-level return signal SIGr<i> indicating correctness.

In addition, in a case where the conduction of the redundant via rV<j> is confirmed, the error detection circuit 82 outputs a signal “0” indicating correctness to the tri-state buffer 83<32+j>. As a result, the tri-state buffer 83<32+j> drives the corresponding control via cV<32+j> to the low level. The determination circuit 55 determines that the corresponding redundant via rV<j> functions correctly by receiving the low-level return signal SIGr<32+j> indicating correctness.

The determination circuit 55 determines that the redundant via rV or the default via dV t of which conduction is not confirmed in step S52 functions incorrectly (S54).

Specifically, in a case where the conduction of the default via dV<i> is not confirmed, the error detection circuit 82 outputs a signal “1” indicating incorrectness to the tri-state buffer 83<i>. As a result, the tri-state buffer 83<i> has high impedance. As a result, the corresponding control via cV<i> is driven to the high level. In a case of receiving the high-level return signal SIGr<i> indicating incorrectness, the determination circuit 55 determines that the corresponding default via dV<i> functions incorrectly.

In addition, in a case where the conduction of the redundant via rV<j> is not confirmed, the error detection circuit 82 outputs a signal “1” indicating incorrectness to the tri-state buffer 83<32+j>. As a result, the tri-state buffer 83<32+j> has high impedance. As a result, the corresponding control via cV<32+j> is driven to the high level. The determination circuit 55 determines that the corresponding redundant via dV<j> functions incorrectly by receiving the high-level return signal SIGr<32+j> indicating incorrectness.

After the processing of step S53 and the processing of step S54, the test process ends (End). Note that, in the example shown in FIG. 22, the processing in step S53 and the processing in step S54 are executed in series, but the present embodiment is not limited thereto. The processing of step S53 and the processing of step S54 may be executed in parallel.

In a case where it is determined in the processing of step S54 that there is an incorrectness in the TSV, a switch process of the TSV may be performed after the test process. Specifically, for example, in response to the determination that the default via dV<0> and the default via dV<1> function correctly, the TSV switching circuit 30-1 is set such that the first state is selected. In response to the determination that the default via dV<0> functions incorrectly and the default via dV<1> functions correctly, the TSV switching circuit 30-1 is set such that the second state or the fourth state is selected. In response to the determination that the default via dV<0> functions correctly and the default via dV<1> functions incorrectly, the TSV switching circuit 30-1 is set such that the third state or the fifth state is selected.

### 5.3 Effects According to Fifth Embodiment

According to the fifth embodiment, the memory device 5 collectively performs conduction confirmation for the redundant vias rV<3:0> and the default vias dV<31:0>. With this configuration, the time required for the test process can be shortened.

### 6. Others

In the second embodiment, the third embodiment, the fourth embodiment, and the fifth embodiment described above, the functional configuration of the core chip 20-4 among the core chips 20-1, 20-2, 20-3, and 20-4 has been described as the functional configuration related to the test process. However, the core chips 20-1, 20-2, and 20-3 may also have the same configuration as the core chip 20-4. As a result, since the core chips 20-1, 20-2, 20-3, and 20-4 can be manufactured by the same process, an increase in manufacturing cost can be suppressed.

Note that, in a case where there is no difference in configuration among the core chips, in the third embodiment, the fourth embodiment, and the fifth embodiment, the tri-state buffer included in each of the core chips 20-1, 20-2, and 20-3 can be connected to the control via cV. In this configuration, the output of the tri-state buffer included in each of the core chips 20-1, 20-2, and 20-3 is controlled to be, for example, high impedance.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A memory device comprising:
a first chip;
a second chip stacked above the first chip, the second chip including a substrate, a memory cell array configured to store data in a non-volatile manner, a first via, a second via, and a third via, each of the first to third vias passing through the substrate in a stacking direction and being connected to the first chip; and
a switching circuit configured to switch among:
a first state in which, between the first chip and the second chip, a first signal is communicated through the first via and a second signal is communicated through the second via;
a second state in which, between the first chip and the second chip, the first signal is communicated through the third via and the second signal is communicated through the second via; and
a third state in which, between the first chip and the second chip, the first signal is communicated through the first via and the second signal is communicated through the third via.

2. The memory device according to claim 1, wherein
the switching circuit includes:
a first switch in the first chip; and
a second switch, a third switch, and a fourth switch in the second chip, wherein
the first switch includes a first terminal to which the first signal is input, a second terminal to which the second signal is input, a third terminal connected to a first terminal of the third via, and a fourth terminal grounded,
the second switch includes a first terminal connected to a first terminal of the first via,
the third switch includes a first terminal connected to a first terminal of the second via, and
the fourth switch includes a first terminal connected to a second terminal of the third via, a second terminal connected to a second terminal of the second switch, and a third terminal connected to a second terminal of the third switch.

3. The memory device according to claim 2, wherein
the switching circuit is further configured to:
in the first state, turn on the second switch and the third switch, and put the third and fourth terminals of the first switch in a connected state;
in the second state, turn on the third switch, turn off the second switch, put the first and third terminals of the first switch in a connected state, and put the first and second terminals of the fourth switch in a connected state; and
in the third state, turn on the second switch, turn off the third switch, put the second and third terminals of the first switch in a connected state, and put the first and third terminals of the fourth switch in a connected state.

4. The memory device according to claim 1, wherein
the switching circuit includes:
a first inverter, a second inverter, a first AND circuit, a second AND circuit, a first NAND circuit, a second NAND circuit, and a third NAND circuit in the first chip; and
a third inverter, a fourth inverter, a fourth NAND circuit, a fifth NAND circuit, a sixth NAND circuit, a seventh NAND circuit, an eighth NAND circuit, and a ninth NAND circuit in the second chip, wherein
each of the first inverter and the third inverter includes an input terminal to which a first control signal is input,
each of the second inverter and the fourth inverter includes an input terminal to which a second control signal is input,
the first AND circuit includes a first input terminal to which the first signal is input, a second input terminal connected to an output terminal of the first inverter, and an output terminal connected to a first terminal of the first via,
the second AND circuit includes a first input terminal to which the second signal is input, a second input terminal connected to an output terminal of the second inverter, and an output terminal connected to a first terminal of the second via,
the first NAND circuit includes a first input terminal to which the first signal is input, and a second input terminal to which the first control signal is input,
the second NAND circuit includes a first input terminal to which the second signal is input, and a second input terminal to which the second control signal is input,
the third NAND circuit includes a first input terminal connected to an output terminal of the first NAND circuit, a second input terminal connected to an output terminal of the second NAND circuit, and an output terminal connected to a first terminal of the third via,
the fourth NAND circuit includes a first input terminal connected to a second terminal of the first via, and a second input terminal connected to an output terminal of the third inverter,
the fifth NAND circuit includes a first input terminal connected to a second terminal of the second via, and a second input terminal connected to an output terminal of the fourth inverter,
the sixth NAND circuit includes a first input terminal to which the first control signal is input, and a second input terminal connected to a second terminal of the third via,
the seventh NAND circuit includes a first input terminal to which the second control signal is input, and a second input terminal connected to the second terminal of the third via,
the eighth NAND circuit includes a first input terminal connected to an output terminal of the fourth NAND circuit, and a second input terminal connected to an output terminal of the sixth NAND circuit, and
the ninth NAND circuit includes a first input terminal connected to an output terminal of the fifth NAND circuit, and a second input terminal connected to an output terminal of the seventh NAND circuit.

5. The memory device according to claim 4, wherein
the switching circuit is further configured to:
in the first state, set the first control signal and the second control signal to a first value;
in the second state, set the first control signal to a second value different from the first value, and set the second control signal to the first value; and
in the third state, set the first control signal to the first value, and set the second control signal to the second value.

6. The memory device according to claim 1, wherein
the switching circuit is further configured to switch among:
the first state;
the second state;
the third state;
a fourth state in which, between the first chip and the second chip, the first signal is communicated through the first via and the third via, and the second signal is communicated through the second via; and
a fifth state in which, between the first chip and the second chip, the first signal is communicated through the first via, and the second signal is communicated through the second via and the third via.

7. The memory device according to claim 6, wherein
the switching circuit includes:
a first switch in the first chip; and
a second switch, a third switch, and a fourth switch in the second chip, wherein
the first switch includes a first terminal to which the first signal is input, a second terminal to which the second signal is input, a third terminal connected to a first terminal of the third via, and a fourth terminal grounded,
the second switch includes a first terminal connected to a first terminal of the first via,
the third switch includes a first terminal connected to a first terminal of the second via, and
the fourth switch includes a first terminal connected to a second terminal of the third via, a second terminal connected to a second terminal of the second switch, and a third terminal connected to a second terminal of the third switch.

8. The memory device according to claim 7, wherein
the switching circuit is further configured to:
in the first state, turn on the second switch and the third switch, and put the third and fourth terminals of the first switch in a connected state;
in the second state, turn on the third switch, turn off the second switch, put the first and third terminals of the first switch in a connected state; and put the first and second terminals of the fourth switch in a connected state;
in the third state, turn on the second switch, turn off the third switch, put the second and third terminals of the first switch in a connected state, and put the first and third terminals of the fourth switch in a connected state;
in the fourth state, turn on the second switch and the third switch, put the first and third terminals of the first switch in a connected state, and put the first and second terminals of the fourth switch in a connected state; and
in the fifth state, turn on the second switch and the third switch, put the second and third terminals of the first switch in a connected state, and put the first and third terminals of the fourth switch in a connected state.

9. The memory device according to claim 6, wherein
the switching circuit includes:
a first AND circuit, a second AND circuit, a first NAND circuit, a second NAND circuit, a third NAND circuit, a tenth NAND circuit, and an eleventh NAND circuit in the first chip; and
a third inverter, a fourth inverter, a first tri-state buffer, and a second tri-state buffer in the second chip, wherein
the tenth NAND circuit includes a first input terminal to which a first control signal is input, and a second input terminal to which a third control signal is input,
the eleventh NAND circuit includes a first input terminal to which a second control signal is input, and a second input terminal to which the third control signal is input,
the first AND circuit includes a first input terminal to which the first signal is input, a second input terminal connected to an output terminal of the tenth NAND circuit, and an output terminal connected to a first terminal of the first via,
the second AND circuit includes a first input terminal to which the second signal is input, a second input terminal connected to an output terminal of the eleventh NAND circuit, and an output terminal connected to a first terminal of the second via,
the first NAND circuit includes a first input terminal to which the first signal is input, and a second input terminal to which the first control signal is input,
the second NAND circuit includes a first input terminal to which the second signal is input, and a second input terminal to which the second control signal is input,
the third NAND circuit includes a first input terminal connected to an output terminal of the first NAND circuit, a second input terminal connected to an output terminal of the second NAND circuit, and an output terminal connected to a first terminal of the third via,
each of the third inverter and the fourth inverter includes an input terminal connected to a second terminal of the third via,
the first tri-state buffer includes an input terminal connected to an output terminal of the third inverter, a control terminal to which the first control signal is input, and an output terminal connected to a second terminal of the first via, and
the second tri-state buffer includes an input terminal connected to an output terminal of the fourth inverter, a control terminal to which the second control signal is input, and an output terminal connected to a second terminal of the second via.

10. The memory device according to claim 9, wherein
the switching circuit is further configured to:
in the first state, set the first control signal and the second control signal to a first value, and set the third control signal to a third value;
in the second state, set the first control signal to a second value different from the first value, set the second control signal to the first value, and set the third control signal to the third value;
in the third state, set the first control signal to the first value, set the second control signal to the second value, and set the third control signal to the third value;
in the fourth state, set the first control signal to the second value, set the second control signal to the first value, and set the third control signal to a fourth value different from the third value; and
in the fifth state, set the first control signal to the first value, set the second control signal to the second value, and set the third control signal to the fourth value.

11. The memory device according to claim 4, wherein
the first chip includes a register, and
the switching circuit is configured to receive the first control signal and the second control signal from the register.

12. The memory device according to claim 4, wherein
the switching circuit is configured to receive the first control signal and the second control signal from outside of the first chip.

13. A testing method for the memory device according to claim 1, the testing method comprising:
transmitting a test signal from the first chip to the second chip through a via selected from the first via, the second via, and the third via; and
determining whether the selected via functions correctly or not based on the test signal having passed through the selected via.

14. The testing method according to claim 13, further comprising:
in a case where the selected via is determined to function correctly, transmitting the test signal through the via determined to function correctly, and transmitting the test signal through another via, which is different from the via determined to function correctly among the first via, the second via, and the third via; and
determining consistency between the test signal having passed through the via determined to function correctly and the test signal having passed through said another via.

15. The testing method according to claim 13, further comprising:
generating the test signal in the first chip.

16. The testing method according to claim 13, further comprising:
generating the test signal in a tester outside of the memory device.

17. A testing method for the memory device according to claim 1, the testing method comprising:
transmitting a test signal from the first chip to the second chip through each of the first via and the third vias;
executing a first process of determining consistency between the test signal having passed through the first via and the test signal having passed through the third via;
transmitting a test signal from the first chip to the second chip through each of the second via and the third via; and
executing a second process of determining consistency between the test signal having passed through the second via and the test signal having passed through the third via.

18. The testing method according to claim 17, further comprising:
in a case where a result of the first process indicates consistency and a result of the second process indicates consistency, determining that the first via, the second via, and the third via function correctly;
in a case where the result of the first process indicates inconsistency and the result of the second process indicates inconsistency, determining that the first via and the second via function correctly and the third via functions incorrectly; and
in a case where one of the result of the first process and the result of the second process indicates consistency and the other indicates inconsistency, determining that one of the first via and the second via corresponding to the process indicating consistency functions correctly, the third via functions correctly, and one of the first via and the second via corresponding to the process indicating inconsistency functions incorrectly.

19. A testing method for the memory device according to claim 1, the testing method comprising:
transmitting a test signal from the first chip to the second chip through each of the first via, the second via, and the third via; and
executing simultaneously determination whether the first via functions correctly or not based on the test signal having passed through the first via, determination whether the second via functions correctly or not based on the test signal having passed through the second via, and determination whether the third via functions correctly or not based on the test signal having passed through the third via.

20. A manufacturing method of the memory device according to claim 1, the manufacturing method comprising:
transmitting a test signal from the first chip to the second chip through a via selected from the first via, the second via, and the third via;
determining whether the selected via functions correctly or not based on the test signal having passed through the selected via;
setting the switching circuit such that the first state is selected in response to determination that the first via and the second via function correctly;
setting the switching circuit such that the second state is selected in response to determination that the first via functions incorrectly and the second via functions correctly; and
setting the switching circuit such that the third state is selected in response to determination that the first via functions correctly and the second via functions incorrectly.
